(19) United States
(12) Patent Application Publication
(10) Pub. No.: US 2025/0336800 A1
(43) Pub. Date: Oct. 30, 2025

(54) DECOUPLING CAPACITORS USING BACKSIDE CONNECTIONS

(71) Applicant: Intel Corporation, Santa Clara, CA (US)

(72) Inventors: Khem C. Pokhrel, El Dorado Hills, CA (US); Changyok Park, Portland, OR (US)

(73) Assignee: Intel Corporation, Santa Clara, CA (US)

(21) Appl. No.: 18/646,019

(22) Filed: Apr. 25, 2024

(51) Int. Cl. H01L 23/522; H01L 23/528

(52) U.S. Cl. CPC H01L 23/5223; H01L 23/5283; H01L 23/5286

(57) ABSTRACT

Techniques are provided herein for forming one or more capacitors between backside power rails using backside contacts to the backside power rails. In one example, a capacitor includes a first plurality of plate-like electrodes that alternate with a second plurality of plate-like electrodes. Backside contacts are used to contact bottom surfaces of the first plurality of plate-like electrodes and bottom surfaces of the second plurality of plate-like electrodes. In another example, a capacitor includes a first plurality of plate-like electrodes and one or more second plate-like electrodes. A dielectric layer is present over the first plurality of plate-like electrodes. A conductive layer is present on the dielectric layer and also contacting at least one of the one or more second plate-like electrodes. Backside contacts are used to contact bottom surfaces of the first plurality of plate-like electrodes and bottom surfaces of the one or more second plate-like electrodes.

### BACKGROUND

As integrated circuits continue to scale downward in size, a number of challenges arise. As density of devices increases, the available space on a given die dwindles rapidly. Some structures require a certain amount of space to operate effectively, but the limited available footprint on a die makes arranging these structures challenging. Accordingly, there remain a number of non-trivial challenges with respect to fabricating certain structures in an integrated circuit.

### BRIEF DESCRIPTION OF THE DRAWINGS

FIG. 1 is a cross-sectional view that illustrates an example portion of an integrated circuit configured with a dielectric region having one or more capacitors laterally adjacent to a device layer having one or more semiconductor devices, in accordance with an embodiment of the present disclosure.

FIGS. 2A-2C are three-dimensional and cross-sectional views of a first capacitor having backside connections to power rails, in accordance with a first embodiment of the present disclosure.

FIGS. 3A-3C are three-dimensional and cross-sectional views of a second capacitor having backside connections to power rails, in accordance with a second embodiment of the present disclosure.

FIGS. 4A and 4B illustrate cross-sectional views of a first stage in a fabrication process for forming either the first capacitor or the second capacitor, in accordance with some embodiments of the present disclosure.

FIGS. 5A and 5B illustrate cross-sectional views of another stage in the fabrication process for forming the first capacitor, in accordance with some embodiments of the present disclosure.

FIGS. 6A and 6B illustrate cross-sectional views of another stage in the fabrication process for forming the first capacitor, in accordance with some embodiments of the present disclosure.

FIGS. 7A and 7B illustrate cross-sectional views of another stage in the fabrication process for forming the first capacitor, in accordance with some embodiments of the present disclosure.

FIGS. 8A and 8B illustrate cross-sectional views of another stage in the fabrication process for forming the first capacitor, in accordance with some embodiments of the present disclosure.

FIGS. 9A and 9B illustrate cross-sectional views of another stage in the fabrication process for forming the first capacitor, in accordance with some embodiments of the present disclosure.

FIGS. 10A and 10B illustrate cross-sectional views of another stage in the fabrication process for forming the first capacitor, in accordance with some embodiments of the present disclosure.

FIGS. 11A and 11B illustrate cross-sectional views of another stage in the fabrication process for forming the first capacitor, in accordance with some embodiments of the present disclosure.

FIGS. 12A and 12B illustrate cross-sectional views of another stage in the fabrication process for forming the first capacitor, in accordance with some embodiments of the present disclosure.

FIGS. 13A and 13B illustrate cross-sectional views of another stage in the fabrication process for forming the first capacitor, in accordance with some embodiments of the present disclosure.

FIGS. 14A and 14B illustrate cross-sectional views of another stage in the fabrication process for forming the second capacitor, in accordance with some embodiments of the present disclosure.

FIGS. 15A and 15B illustrate cross-sectional views of another stage in the fabrication process for forming the second capacitor, in accordance with some embodiments of the present disclosure.

FIGS. 16A and 16B illustrate cross-sectional views of another stage in the fabrication process for forming the second capacitor, in accordance with some embodiments of the present disclosure.

FIGS. 17A and 17B illustrate cross-sectional views of another stage in the fabrication process for forming the second capacitor, in accordance with some embodiments of the present disclosure.

FIGS. 18A and 18B illustrate cross-sectional views of another stage in the fabrication process for forming the second capacitor, in accordance with some embodiments of the present disclosure.

FIGS. 19A and 19B illustrate cross-sectional views of another stage in the fabrication process for forming the second capacitor, in accordance with some embodiments of the present disclosure.

FIGS. 20A and 20B illustrate cross-sectional views of another stage in the fabrication process for forming the second capacitor, in accordance with some embodiments of the present disclosure.

FIGS. 21A and 21B illustrate cross-sectional views of another stage in the fabrication process for forming the second capacitor, in accordance with some embodiments of the present disclosure.

FIGS. 22A and 22B illustrate cross-sectional views of another stage in the fabrication process for forming the second capacitor, in accordance with some embodiments of the present disclosure.

FIGS. 23A and 23B illustrate cross-sectional views of another stage in the fabrication process for forming the second capacitor, in accordance with some embodiments of the present disclosure.

FIGS. 24A and 24B illustrate cross-sectional views of another stage in the fabrication process for forming the second capacitor, in accordance with some embodiments of the present disclosure.

FIGS. 25A and 25B illustrate cross-sectional views of another stage in the fabrication process for forming the second capacitor, in accordance with some embodiments of the present disclosure.

FIG. 26 illustrates a cross-section view of a chip package containing one or more semiconductor dies, in accordance with an embodiment of the present disclosure.

FIG. 27 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein for forming one or more capacitors between power rails and/or signal lines. Although the techniques can be used in any number of integrated circuit applications, they are particularly useful with respect to forming decoupling capacitors in regions laterally adjacent to (or within) the device layer of an integrated circuit. In a first example, a capacitor within a dielectric region laterally adjacent to a device layer includes a first plurality of plate-like electrodes that alternate with a second plurality of plate-like electrodes. A dielectric material may be present between each adjacent pair of plate-like electrodes. A first plurality of contacts may be on a bottom or backside surface of the first plurality of plate-like electrodes, and a second plurality of contacts may be on a bottom or backside surface of the second plurality of plate-like electrodes. In a second example, a capacitor within a dielectric region laterally adjacent to a device layer includes a first plurality of plate-like electrodes and one or more second plate-like electrodes. A dielectric layer is present over the first plurality of plate-like electrodes. A conductive layer is present on the dielectric layer and also contacting at least one of the one or more second plate-like electrodes. A first plurality of contacts may be on a bottom or backside surface of the first plurality of plate-like electrodes and one or more second contacts may be on a bottom or backside surface of the one or more second plate-like electrodes. Numerous configurations and variations will be apparent in light of this disclosure.

### General Overview

As previously noted above, it can be challenging to provide effective area scaling for capacitor structures. Passive metal-insulator-metal (MIM) capacitors protect against power delivery noise and can provide a charge reservoir close to the transistors. Their performance is measured in capacitance/area. Typical MIM capacitors stack electrode and high-K dielectric films in a planar fashion, which makes the capacitance directly dependent on the occupied two-dimensional area. However, it becomes increasingly challenging to integrate such capacitors in densely packed devices with limited available footprint. Furthermore, using multiple additional processing steps to form the capacitors increases the cost and complexity of the integrated circuit.

Thus, techniques are provided herein for forming capacitors in a dielectric region laterally adjacent to the device region that use backside contacts to couple with power rails or signal lines. According to an embodiment, a capacitor includes multiple parallel conductive plates (e.g., electrodes) with a dielectric material between each pair of adjacent plates. The plates may be arranged in a single line like a set of dominos with their respective lengths all extending along a same first direction. In some embodiments, each of the conductive plates has substantially the same dimensions (height, width, and length). The conductive plates may include first electrodes that alternate with second electrodes of the capacitor. Each of the first electrodes (e.g., first subset of the conductive plates) may include a first backside contact on a bottom surface of the first electrode, and each of the second electrodes (e.g., second subset of the conductive plates) may include a second backside contact on a bottom surface of the second electrode. The first backside contacts may contact a first backside power rail or signal line and the second backside contacts may contact a second backside power rail or signal line.

In another example design, a capacitor includes multiple parallel conductive plates (e.g., electrodes) as described above. The conductive plates may include a plurality of first electrodes and one or more second electrodes of the capacitor. A dielectric layer (e.g., a thin liner) may extend over the top and side surfaces of the plurality of first electrodes. A conductive layer may contact the dielectric layer and also contact at least one of the one or more second electrodes. Each of the first electrodes (e.g., first subset of the conductive plates) may include a first backside contact on a bottom surface of the first electrode, and each of the one or more second electrodes (e.g., second subset of the conductive plates) may include a second backside contact on a bottom surface of the second electrode. The first backside contacts may contact a first backside power rail or signal line and the second backside contacts may contact a second backside power rail or signal line.

In any of the capacitor designs described herein, the capacitors may be used as decoupling capacitors between backside power rails (e.g., between VDD and VSS rails or between VDD and ground rails) that extend beneath the semiconductor devices. A decoupling capacitor effectively provides a pathway to ground for alternating current (AC) noise (e.g., ground bounce, or ripple attributable to power supply switching) that is manifesting on a given power rail. In this manner, a decoupling capacitor filters out or decouples AC noise from a DC power rail, to provide a higher quality power supply. In some embodiments, the capacitors may also be coupled between backside signal lines or between one backside power rail and one backside signal line, depending on the circuit arrangement.

According to an embodiment, an integrated circuit includes a plurality of semiconductor devices in a device layer and a capacitor within a dielectric region that is laterally adjacent to the device layer. The capacitor includes a plurality of first electrodes, each having a height in a first direction through an entire thickness of the dielectric region and having a length along a second direction, a plurality of second electrodes, each having a height in the first direction through the entire thickness of the dielectric region and having a length along the second direction, a first plurality of contacts on a backside of the plurality of first electrodes, and a second plurality of contacts on a backside of the plurality of second electrodes. The first plurality of contacts are beneath a bottom surface of the plurality of first electrodes and the second plurality of contacts are beneath a bottom surface of the plurality of second electrodes. The plurality of first electrodes alternates with the plurality of second electrodes along a third direction substantially orthogonal to the second direction.

According to another embodiment, an integrated circuit includes a plurality of semiconductor devices in a device layer, and a capacitor within a dielectric region that is laterally adjacent to the device layer. The capacitor includes a plurality of first electrodes, each having a height in a first direction, a length along a second direction, and arranged parallel to one another along a third direction, one or more second electrodes, each having a height in the first direction, a length along the second direction, and arranged parallel to the plurality of first electrodes along the third direction, a dielectric layer over an outer surface of the plurality of first electrodes, a conductive layer on the dielectric layer and between two or more of the plurality of first electrodes, a first plurality of contacts on a backside of the plurality of first electrodes, and one or more second contacts on a backside of the one or more second electrodes. The conductive layer contacts at least one of the one or more second electrodes. The first plurality of contacts are beneath a bottom surface of the plurality of first electrodes and the one or more second contacts are beneath a bottom surface of the one or more second electrodes.

The techniques can be used with any type of planar and non-planar transistors, including finFETs (sometimes called double-gate transistors, or tri-gate transistors), nanowire and nanoribbon transistors (sometimes called gate-all-around transistors), and thin film transistors, to name a few examples. The source and drain regions can be, for example, epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a remove metal gate, or RMG, process). Any number of semiconductor materials can be used in forming the transistors to which power is being supplied by a backside power rail, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of one or more capacitors with electrodes in a dielectric region laterally adjacent to a device layer (e.g., having one or more semiconductor devices). The capacitors include backside contacts to the electrodes that connect the electrodes to backside power rails or backside signal lines.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer.

### Architecture

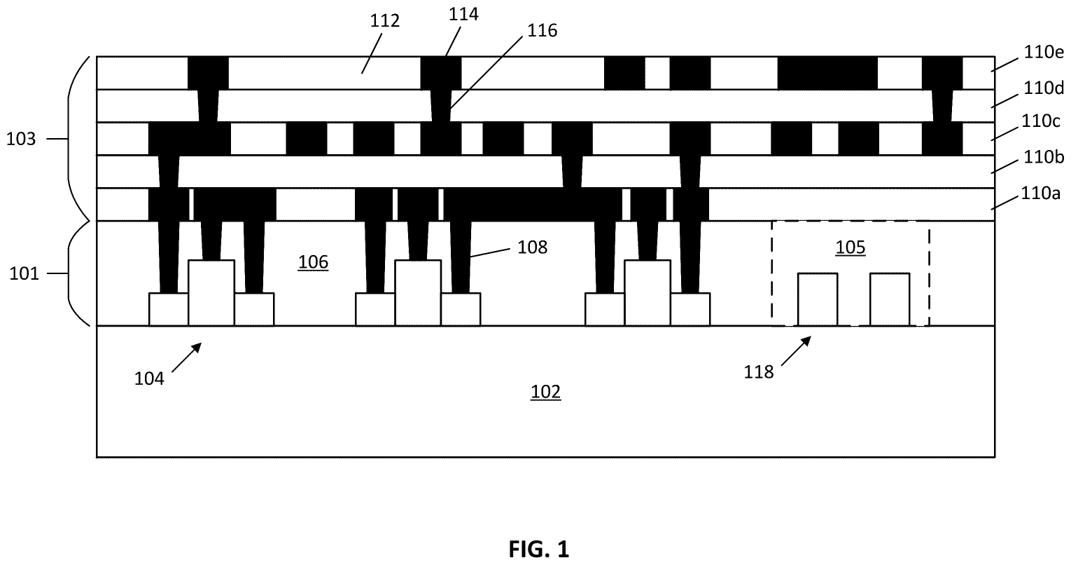

FIG. 1 is a cross-sectional view that illustrates an example portion of an integrated circuit having an interconnect region above a plurality of semiconductor devices within a device layer, in accordance with an embodiment of the present disclosure. The semiconductor devices in this example are non-planar metal oxide semiconductor (MOS) transistors, such as tri-gate or gate-all-around (GAA) transistors, although other transistor topologies and types can also benefit from the techniques provided herein, as will be appreciated (e.g., planar transistors, forksheet transistors, thin film transistors, or any other transistors to which contact can be made).

According to some embodiments, the integrated circuit includes a device layer 101 (sometimes referred to as a device region), and an interconnect region 103 over the device layer 101. A dielectric region 105 is also provided laterally adjacent to device layer 101. Device layer 101 may include a plurality of semiconductor devices 104 along with one or more other layers or structures associated with the semiconductor devices 104. For example, device layer 101 can also include one or more dielectric layers 106 that surround active portions or contacts of the semiconductor devices 104. Device layer 101 may also include one or more conductive contacts 108 that provide electrical contact to transistor elements such as gate structures, drain regions, or source regions. Conductive contacts 108 include, for example, tungsten, although other metal or metal alloy materials may be used as well. Conductive contacts may also be a part of, or otherwise include, what is sometimes called a local interconnect, which is considered part of the device layer and usually formed prior to any backend processing.

In some embodiments, device layer 101 is formed on or over a substrate 102.

Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, backside processing is used to remove substrate 102 and form any number of backside interconnect layers.

Interconnect region 103 includes a plurality of interconnect layers 110a-110e stacked over one another. Each interconnect layer can include a dielectric material 112 along with one or more different conductive features. Dielectric material 112 can be any dielectric, such as silicon oxide, silicon oxycarbide, silicon nitride, or silicon oxynitride. Dielectric material 112 may be deposited using any known dielectric deposition technique such as chemical vapor deposition (CVD), plasma-enhanced chemical vapor deposition (PECVD), flowable CVD, spin-on dielectric, or atomic layer deposition (ALD). The one or more conductive features can include conductive traces 114 and conductive vias 116 arranged in any pattern across the interconnect layers 110a-110e to carry signal and/or power voltages to/from the various semiconductor devices 104. A conductive via, such as conductive via 116, may extend through an interconnect layer to connect between conductive traces on an upper interconnect layer and a lower interconnect layer. In other cases, a via 116 may only extend part way through a given interconnect layer. Although interconnect region 103 is illustrated with only five interconnect layers, any number of interconnect layers can be used within interconnect region 103. Also, this example shows vias and lines in different interconnect layers, in both single and dual damascene configurations. In other examples, vias and lines may also exist within the same interconnect layer, such as in the case of some dual damascene configurations.

Any of conductive traces 114 and conductive vias 116 can include any number of conductive materials, with some examples including copper, ruthenium, tungsten, cobalt, molybdenum, and alloys thereof. In some cases, any of conductive traces 114 and conductive vias 116 include a relatively thin liner or barrier, such as titanium nitride, titanium silicide, tungsten carbo-nitride (WCN), PVD or ALD tungsten, or tantalum nitride.

According to some embodiments, dielectric region 105 includes the same dielectric material as one or more dielectric layers 106. A top surface of dielectric region 105 may be substantially coplanar with a top surface of device layer 101. According to some embodiments, dielectric region 105 includes one or more capacitors 118. Capacitors 118 may include electrodes with backside contacts to backside conductive lines (e.g., within substrate 102 or within one or more backside interconnect layers beneath semiconductor devices 104 and capacitors 118). Accordingly, capacitors 118 may act as decoupling capacitors to backside power rails or as capacitors between backside signal lines, depending on the circuit arrangement.

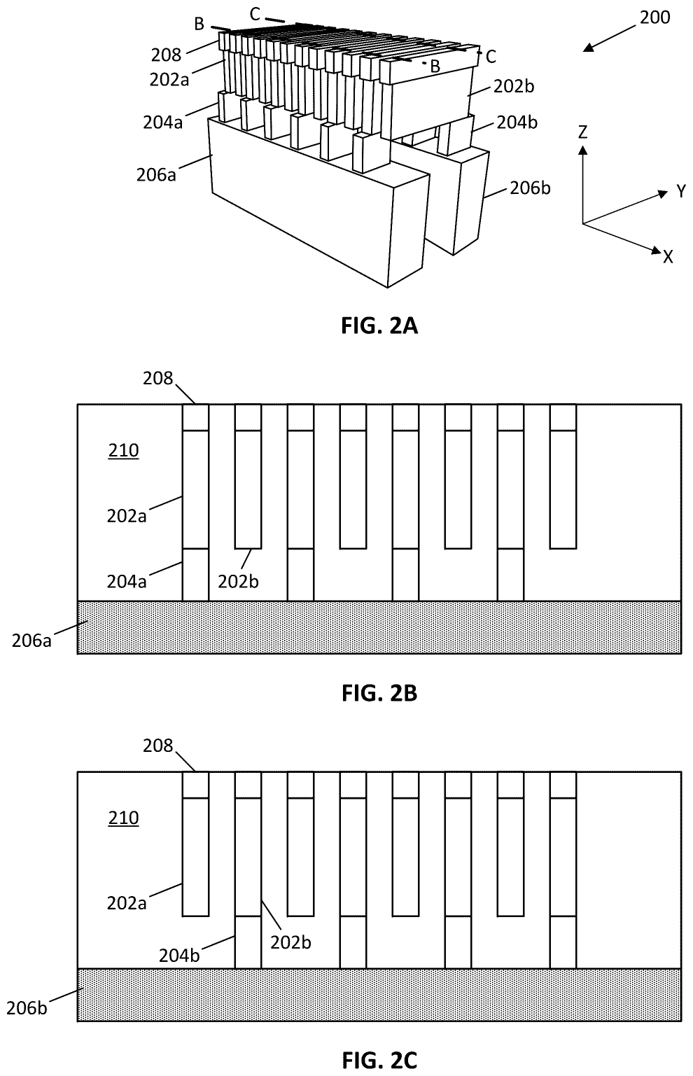

FIG. 2A illustrates a three-dimensional view of a first example capacitor 200, according to some embodiments. FIGS. 2B and 2C illustrate cross sections taken across lines B-B and C-C, respectively, of capacitor 200. Note that FIG. 2A omits all dielectric material so as to not obfuscate viewing of the arrangement of the conductive features of capacitor 200. The omitted dielectric material may include, for instance, dielectric fill or dielectric walls, and capacitor dielectric between the capacitor plates or electrodes.

According to some embodiments, capacitor 200 includes a plurality of first electrodes 202a and a plurality of second electrodes 202b. Each electrode may have the geometry of a plate or rectangular prism with a height extending in a first direction (e.g., Z-direction), a length extending in a second direction (e.g., Y-direction), and a width extending in a third direction (e.g., X-direction). Each of the plurality of first electrodes 202a may include or be on a corresponding first backside contact 204a, and each of the plurality of second electrodes 202b may include or be on a corresponding second backside contact 204b. First backside contacts 204a connect to a first backside conductive layer 206a (also called a power rail herein), and second backside contacts 204b connect to a second backside conductive layer 206b.

According to some embodiments, the plurality of first electrodes 202a alternate with the plurality of second electrodes 202b along the third direction. Put another way, each first electrode 202a may be separated from the closest next first electrode 202a by a second electrode 202b along the third direction. The plurality of first and second electrodes 202a, 202b may be aligned together along the third direction like an arranged line of dominos. According to some embodiments, each of the plurality of first and second electrodes 202a, 202b has substantially the same dimensions. For example, each electrode 202a, 202b may have a height in the first direction between about 50 nm and about 200 nm, a length in the second direction between about 50 nm and about 300 nm, and a thickness in the third direction between about 10 nm and about 50 nm. Other examples may be configured differently.

First backside conductive layer 206a runs substantially parallel to second backside conductive layer 206b, according to some embodiments. Accordingly, first backside contacts 204a may contact the underside of first electrodes 202a at a first end (e.g., the near end in FIG. 2A) of first electrodes 202a, while second backside contacts 204b may contact the underside of second electrodes 202b at an opposite second end (e.g., the far end in FIG. 2A) of second electrodes 202b. Conductive layers 206a and 206b may be referred to as backside layers, as they may be underneath a given device layer that includes capacitor 200 and effectively buried in or surrounded by dielectric material. Other examples may be configured differently, and the term buried or backside is not intended to limit conductive layers 206a and 206b to a specific structure or configuration; rather, conductive layers 206a and 206b may have any number of configurations, including straight, meandering, short, or long conductive lines.

According to some embodiments, each of the plurality of first electrodes 202a and second electrodes 202b includes a conductive cap 208 that further extends the height of the electrodes. Conductive cap 208 may be the same conductive material as first electrodes 202a and second electrodes 202b, or it may be a different conductive material. According to some embodiments, each of the plurality of first and second electrodes 202a, 202b and conductive caps 208 includes any suitable conductive material, such as tungsten, ruthenium, molybdenum, or cobalt to name a few examples. Similarly, first and second backside contacts 204a, 204b and conductive layers 206a, 206b may include any suitable conductive material, such as tungsten, ruthenium, molybdenum, or cobalt to name a few examples. According to some embodiments, first backside conductive layer 206a is a first power rail (e.g., VDD or VSS) and second backside conductive layer 206b is a second power rail (e.g., VSS or VDD) with a different polarity than the first power rail. In some embodiments, either of first backside conductive layer 206a or second backside conductive layer 206b is grounded. In still other embodiments, either or both of first backside conductive layer 206a or second backside conductive layer 206b is a signal line.

FIGS. 2B and 2C illustrate cross-section views from different ends of the first and second electrodes 202a, 202b. According to some embodiments, a dielectric region 210 is provided between and around each of first and second electrodes 202a, 202b, and provides the capacitor dielectric. In some examples, dielectric region 210 is also laterally adjacent to both first backside contacts 204a and second backside contacts 204b. Dielectric region 210 may include any number of dielectric layers having any suitable dielectric material, such as silicon dioxide. In some examples, a high-k dielectric material may be used between first and second electrodes 202a, 202b, such as hafnium oxide, aluminum oxide, or silicon nitride. The alternating connections to either first backside conductive layer 206a or to second backside conductive layer 206b can be seen across the horizontal arrangement of first and second electrodes 202a, 202b. Any number of alternating electrodes can be used to either increase or decrease the size and total capacitance of capacitor 200. Higher capacitance can also be achieved by increasing the dielectric constant (k) of the capacitor dielectric material. In some examples, the spacing between adjacent first and second electrodes 202a and 202b may be adjusted to also affect the total capacitance of capacitor 200. Accordingly, each of first electrodes 202a provides a first terminal of capacitor 200 and each of second electrodes 202b provides the second terminal of capacitor 200, having dielectric region 210 between the two capacitor terminals.

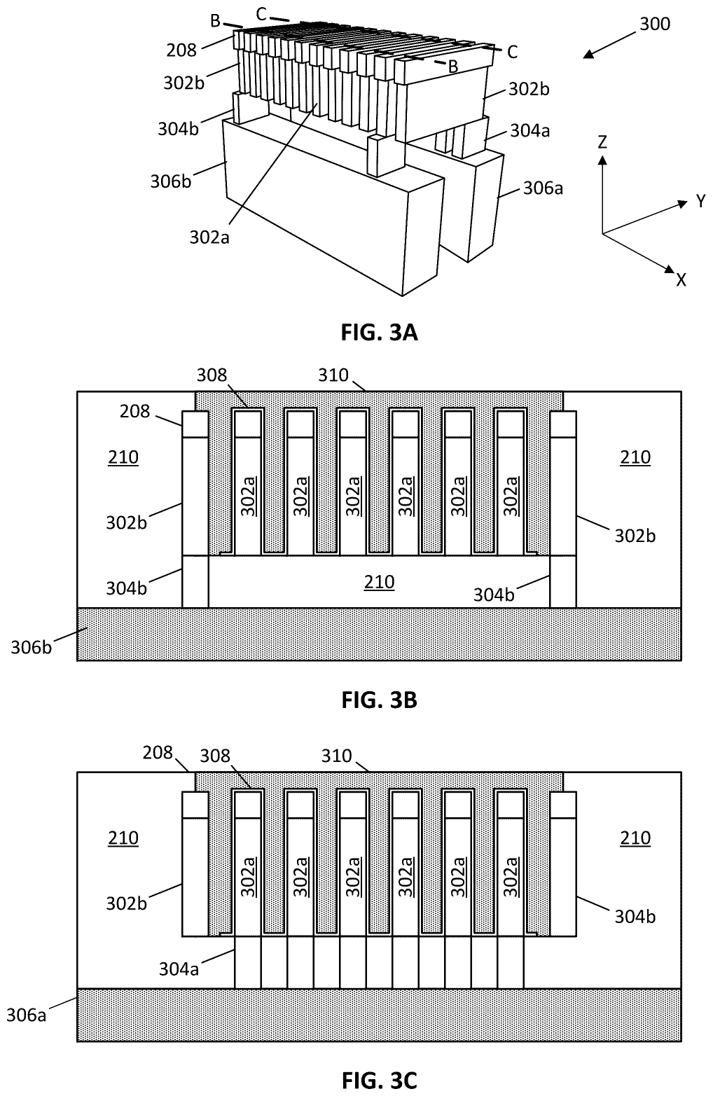

FIG. 3A illustrates a three-dimensional view of a second example capacitor 300, according to some embodiments. FIGS. 3B and 3C illustrate cross sections taken across lines B-B and C-C, respectively, of capacitor 300. Note that FIG. 3A omits all dielectric material and the top conductive layer so as to not obfuscate viewing of the arrangement of the electrodes of capacitor 300.

Like capacitor 200, capacitor 300 includes a similar arrangement of plate-like electrodes arranged parallel to one another in a line along the third direction. Capacitor 300 includes a plurality of first electrodes 302a and a plurality of second electrodes 302b. The general dimensions and positions of the electrodes of capacitor 300 may be the same as those described above for capacitor 200, and similarly can vary from one example to the next.

According to some embodiments, capacitor 300 includes a plurality of first electrodes 302a and one or more second electrodes 302b. Unlike capacitor 200, first electrodes 302a of capacitor 300 may be arranged laterally adjacent to one another along the third direction (e.g., with no second electrode 302b spaced between along the third direction). In the illustrated example, plurality of first electrodes 302a are arranged laterally adjacent to one another in a line along the third direction and a second electrode 302b is arranged at opposite ends of the line of first electrodes 302a. In some examples, only a single second electrode 302b is arranged at one end of the line of first electrodes 302a (e.g., no second electrode at the opposite end of the line). In some examples, only a single second electrode 302b is arranged anywhere along the line of first electrodes 302a (e.g., separating the line of first electrodes 302a into two separate lines of first electrodes 302a.

Like capacitor 200, each of the plurality of first electrodes 302a may include a corresponding first backside contact 304a, and each of the one or more second electrodes 302b may include a corresponding second backside contact 304b. First backside contacts 304a connect to first backside conductive layer 306a, and second backside contacts 304b connect to a second backside conductive layer 306b. First backside conductive layer 306a and second backside conductive layer 306b may be substantially the same as first backside conductive layer 206a and second backside conductive layer 206b described above for capacitor 200.

As shown in the cross-section views of FIGS. 3B and 3C, a dielectric layer 308 is provided over the side and top surfaces of plurality of first electrodes 302a (or over the top surface of conductive cap 208, if they are included), and provides the capacitor dielectric. Note that dielectric layer 308 is not on any portion of one or more second electrodes 302b, according to some embodiments. Dielectric layer 308 may be a thin high-k dielectric material, such as aluminum oxide or hafnium oxide, with a thickness for instance between about 1 nm and about 5 nm. According to some embodiments, a conductive layer 310 is on dielectric layer 308 and also on at least one of one or more second electrodes 302b. Accordingly, each of first electrodes 302a provides a first terminal of capacitor 300 and conductive layer 310 provides the second terminal of capacitor 300, having dielectric layer 308 between the two capacitor terminals. Conductive layer 310 may be any suitable conductive material, such as tungsten, ruthenium, cobalt, or molybdenum. In some examples, conductive layer 310 and plurality of first electrodes 302a have the same conductive material composition. Backside connection is made to the first capacitor terminal via each of first backside contacts 304a and backside connection is made to the second capacitor terminal via each of the one or more second backside contacts 304b, according to some embodiments. First backside contacts 304a and second backside contacts 304b may be substantially the same as first backside contacts 204a and second backside contacts 204b described above for capacitor 200.

### Fabrication Methodology

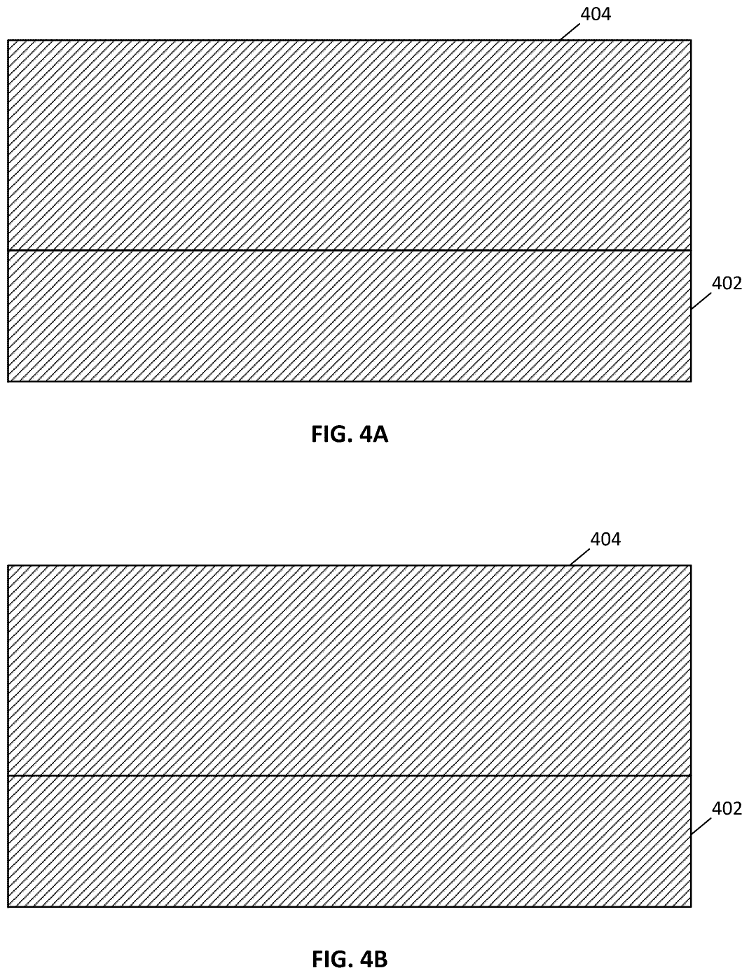

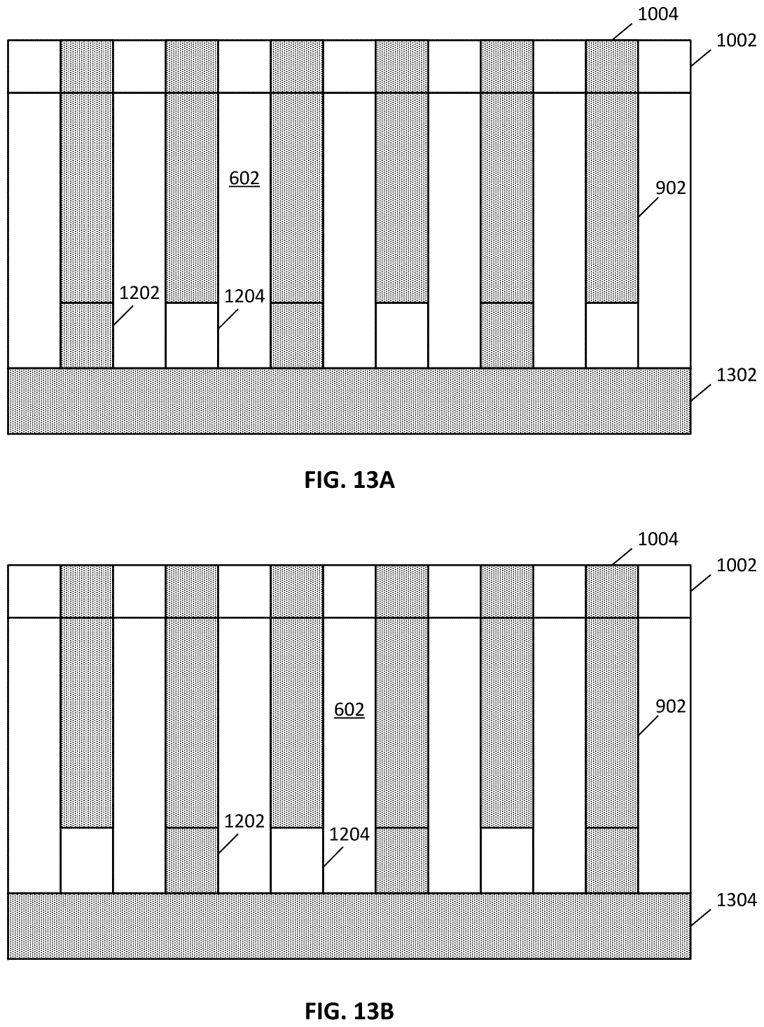

FIGS. 4A-13A and 4B-14B include cross-sectional views that collectively illustrate an example process for forming a portion of an integrated circuit having a first capacitor design using backside connections to backside conductive lines, in accordance with an embodiment of the present disclosure. FIGS. 4A-13A represent a similar cross-sectional view taken across plane B-B of FIG. 2A, while FIGS. 4B-13B represent a similar cross-sectional view taken across plane C-C of FIG. 2A. Each set of figures sharing the same letter shows an example structure that results from the process flow up to that point in time, so the depicted structure evolves as the process flow continues, culminating in the structures shown in FIGS. 13A and 13B, which is similar to the capacitor structure depicted in FIGS. 2A-2C. Such structures may be part of an overall integrated circuit (e.g., such as a processor or memory chip) that includes, for example, digital logic cells and/or memory cells and analog mixed signal circuitry. Thus, the illustrated portion of an integrated circuit structure may be part of a larger integrated circuit that includes other integrated circuitry not depicted. Example materials and process parameters are given, but the present disclosure is not intended to be limited to any specific such materials or parameters, as will be appreciated.

FIGS. 4A and 4B are cross sectional views taken through a portion of a substrate 402 having a device layer 404 on it, according to some embodiments. Substrate 402 may be substantially similar to substrate 102 discussed above with reference to FIG. 1. Accordingly, substrate 402 may include any suitable semiconductor material, although other substrate materials (e.g., dielectric substrates) can be used as well.

Device layer 404 may include any suitable semiconductor material or multiple layers of semiconductor material. In some examples, device layer 404 includes a single layer of silicon or silicon germanium with a thickness between about 50 nm and about 200 nm. In some examples, device layer 404 includes alternating layers of different semiconductor materials, such as alternating silicon layers with silicon germanium layers.

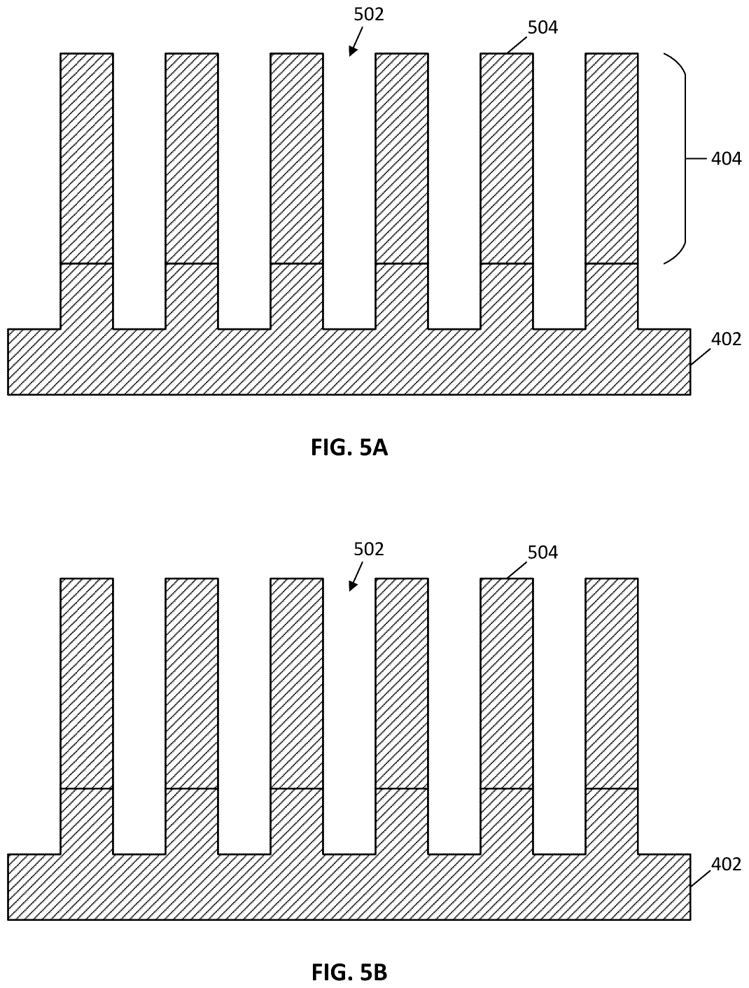

FIGS. 5A and 5B are cross sectional views of the structure shown in FIGS. 4A and 4B following the formation of trench recesses 502 through at least a portion of the total thickness of device layer 404, according to some embodiments. A reactive ion etching (RIE) process may be used along with a patterned hard mask or photoresist to etch through device layer 404 and form the parallel recesses 502. The etch pattern may form parallel trenches such that recesses 502 extend into and out of the page a given distance. The formation of recesses 502 leaves behind semiconductor walls 504 between recesses 502 having a height in a first direction and extending into and out of the page in a second direction orthogonal to the first direction. According to some embodiments, recesses 502 extend through an entire thickness of device layer 404. According to some embodiments, recesses 502 extend into at least a portion of substrate 402. In some embodiments, the same etching process used to form fins of semiconductor material to make transistors in the device region is also used to form recesses 502.

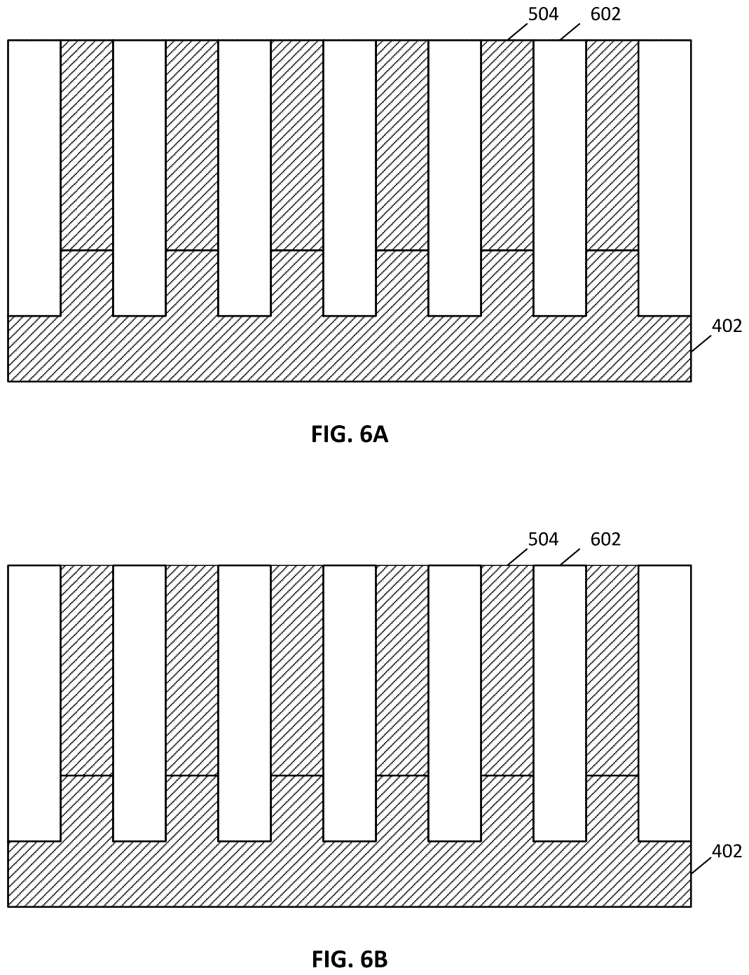

FIGS. 6A and 6B are cross sectional views of the structure shown in FIGS. 5A and 5B following the formation of dielectric walls 602 within recesses 502, according to some embodiments. Dielectric walls 602 may be any suitable dielectric material, such as silicon dioxide. In some examples, dielectric walls 602 include a high-k dielectric material. A top surface of dielectric walls 602 may be polished using, for example, chemical mechanical polishing (CMP) until it is substantially coplanar with a top surface of semiconductor walls 504. In some embodiments, dielectric walls 602 extend into at least a portion of substrate 402, depending on the depth of recesses 502.

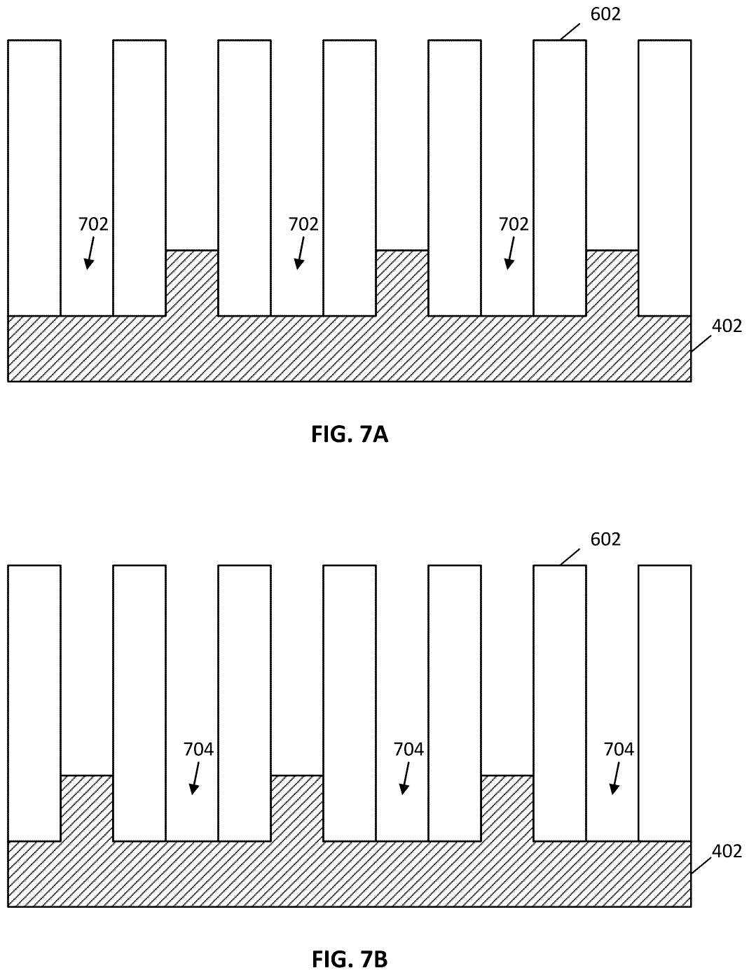

FIGS. 7A and 7B are cross sectional views of the structure shown in FIGS. 6A and 6B following the removal of semiconductor walls 504 and selective removal of portions of substrate 402, according to some embodiments. Any number of RIE processes and lithography processes can be used to remove the semiconductor material of semiconductor walls 504, and to selectively remove portions of the substrate at different ends of the trench-like recesses between dielectric walls 602. According to some embodiments, first cavities 702 are formed by removing portions of substrate 402 between adjacent dielectric walls 602. First cavities 702 alternate along a third direction (e.g., across the page) with portions of substrate 402 that remain between adjacent dielectric walls 602. On the other side of the trench-like openings (e.g., further into or out of the page), second cavities 704 alternate along the third direction with portions of substrate 402 that remain between adjacent dielectric walls 602. According to some embodiments, first cavities 702 and second cavities 704 alternate along the third direction, such that the trench-like openings along the third direction alternate with regards to whether they include first cavity 702 at one end or second cavity 704 at an opposite end along the second direction (e.g., into and out of the page). Each of first and second cavities 702, 704 may have substantially the same depth.

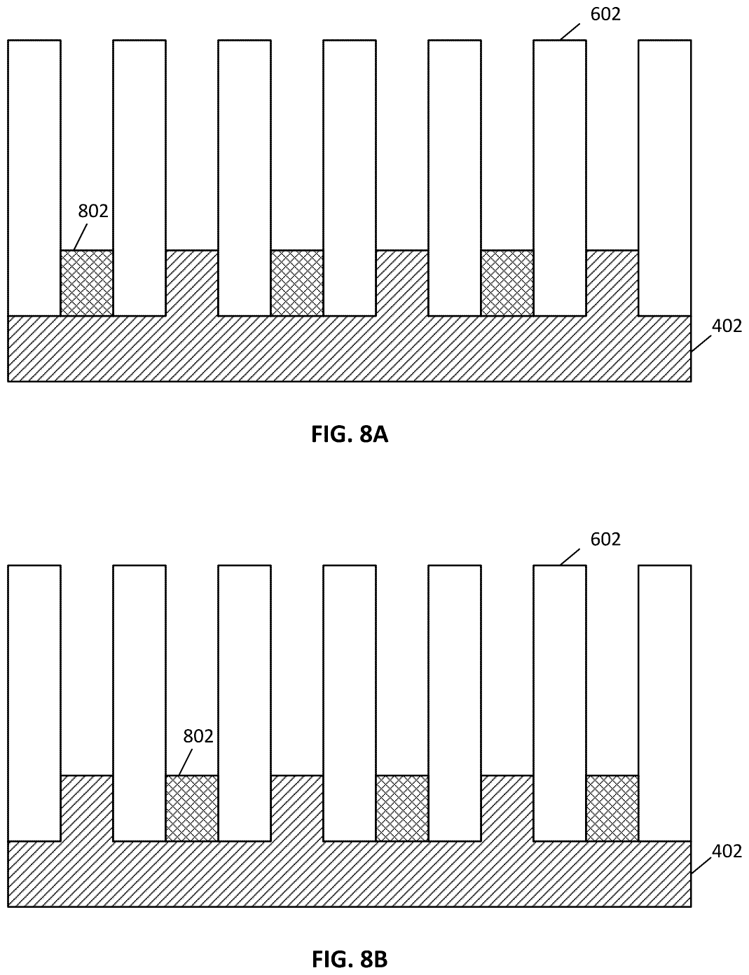

FIGS. 8A and 8B are cross sectional views of the structure shown in FIGS. 7A and 7B following the formation of sacrificial material 802 within each of first cavities 702 and second cavities 704, according to some embodiments. Sacrificial material 802 may be any suitable material that can be removed at a later time without damaging surrounding materials. In some examples, sacrificial material 802 includes aluminum oxide or titanium nitride. According to some embodiments, sacrificial material 802 may be deposited using any suitable deposition technique such as chemical vapor deposition (CVD), plasma-enhanced chemical vapor deposition (PECVD), or physical vapor deposition (PVD). Sacrificial material 802 may be recessed until a top surface of sacrificial material 802 is near (e.g., within 10 nm) of a top surface of substrate 402.

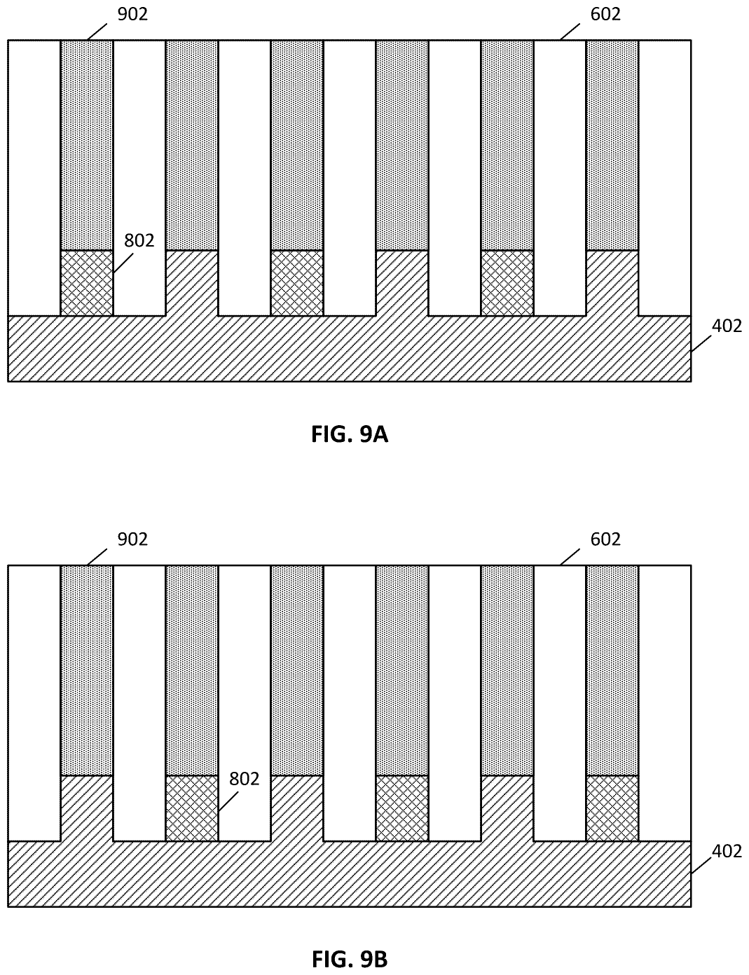

FIGS. 9A and 9B are cross sectional views of the structure shown in FIGS. 8A and 8B following the formation of conductive fill 902 within the trench-like recesses between dielectric walls 602, according to some embodiments. Conductive fill 902 may include any suitable conductive material, such as tungsten, cobalt, ruthenium, or molybdenum. According to some embodiments, a top surface of conductive fill 902 may be polished to be substantially coplanar with a top surface of dielectric walls 602. Conductive fill 902 may form parallel conductive plates arranged in a line along the third direction. According to some embodiments, conductive fill 902 forms the electrode structures for the capacitor.

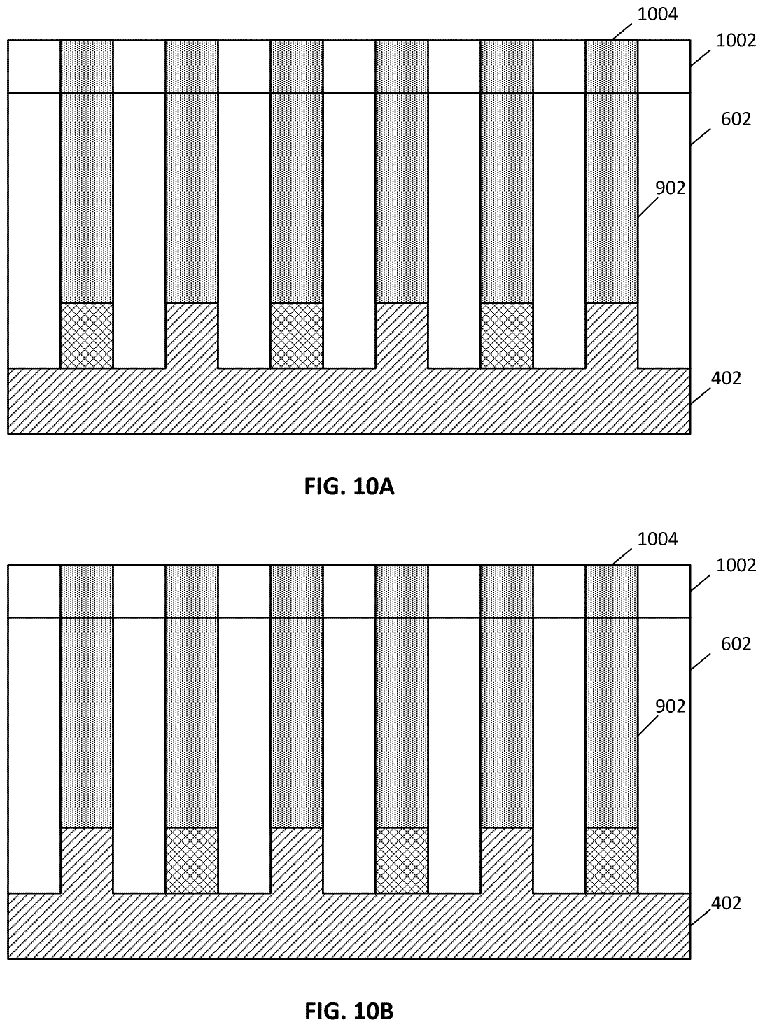

FIGS. 10A and 10B are cross sectional views of the structure shown in FIGS. 9A and 9B following the formation of a top dielectric layer 1002 and conductive caps 1004, according to some embodiments. Top dielectric layer 1002 may include any suitable dielectric material, such as silicon dioxide. In some examples, top dielectric layer 1002 includes the same dielectric material as dielectric walls 602. Conductive caps 1004 may be provided through a thickness of top dielectric layer 1002 and contacting a top surface of conductive fill 902. Due to possible alignment error, conductive caps 1004 may be slightly offset from conductive fill 902. As noted above, conductive caps 1004 may include the same conductive material as conductive fill 902. In some embodiments, conductive caps 1004 include any of tungsten, cobalt, ruthenium, or molybdenum.

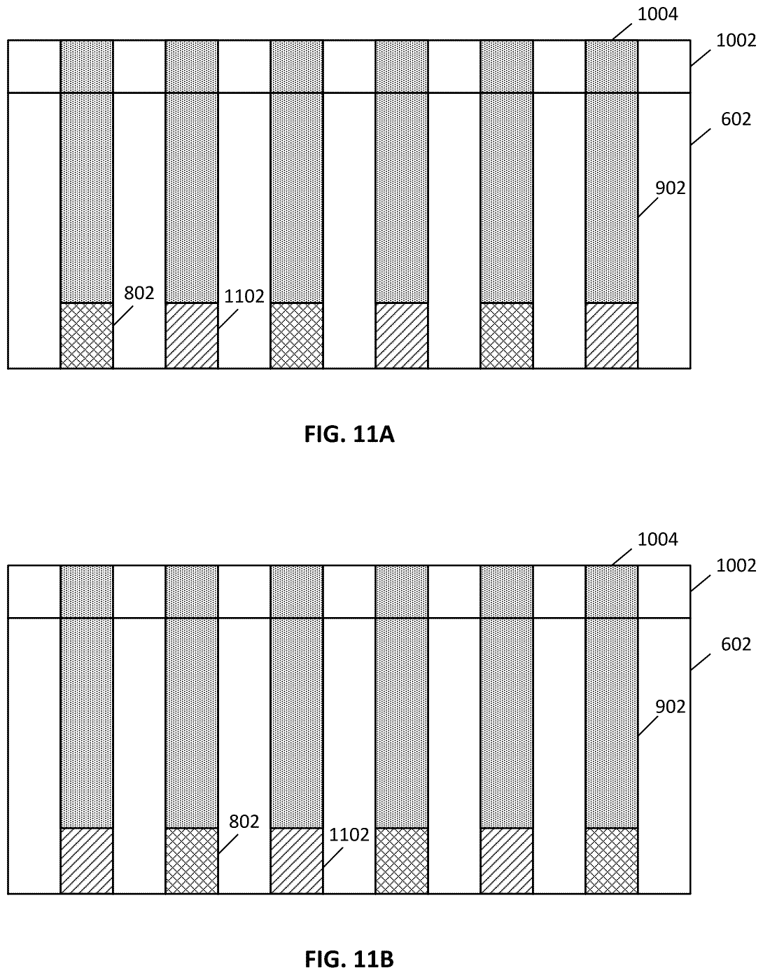

FIGS. 11A and 11B are cross sectional views of the structure shown in FIGS. 10A and 10B following the removal of substrate 402 from the backside, according to some embodiments. Substrate 402 may be removed using any number of grinding, polishing, or etching processes that remove semiconductor material. According to some embodiments, substrate 402 may be removed until a bottom surface of sacrificial material 802 is exposed. In some embodiments, substrate plugs 1102 may remain between the lower portions of adjacent walls of dielectric walls 602.

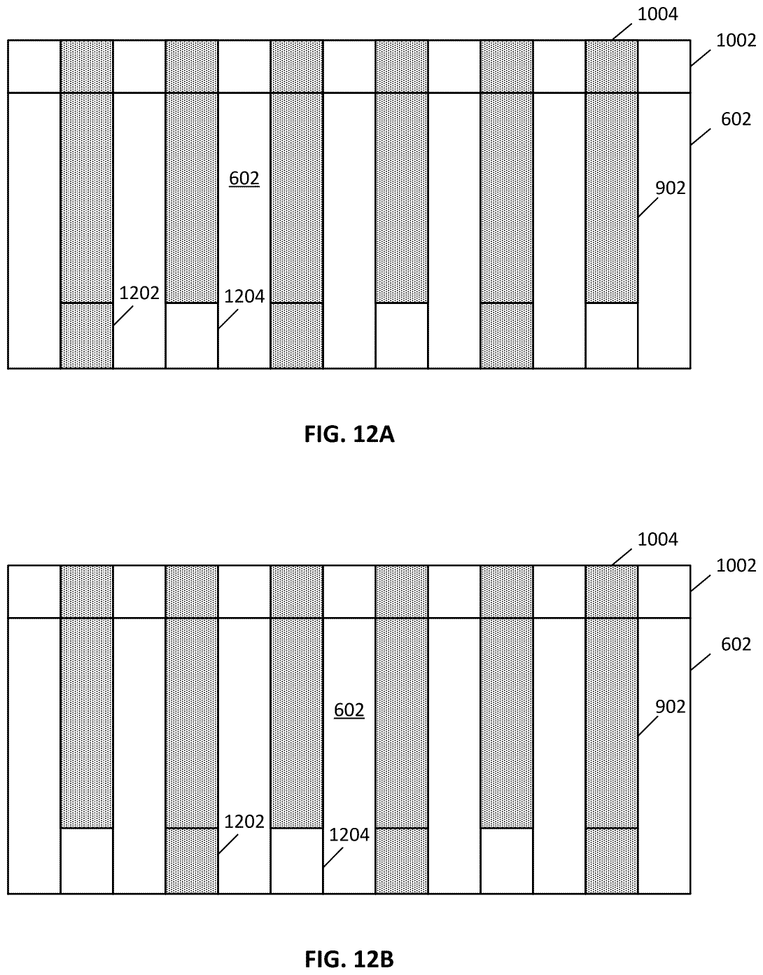

FIGS. 12A and 12B are cross sectional views of the structure shown in FIGS. 11A and 11B following the replacement of sacrificial material 802 with backside contacts 1202, according to some embodiments. In examples where substrate plugs 1102 are present, these may also be replaced with additional dielectric fill 1204. An isotropic etching process may be used to remove sacrificial material 802 from the backside to form backside cavities that expose portions of the bottom surfaces of conductive fill 902. A conductive material may be formed within the backside cavities to form backside contacts 1202 on the bottom or backside surfaces of conductive fill 902. Due to the alternating arrangement of sacrificial material 802 on either end of conductive fill 902, backside contacts 1202 follow the same alternating arrangement on the bottom surfaces of either end of conductive fill 902.

In examples where substrate plugs 1102 remain, the semiconductor material of substrate plugs 1102 may be removed using an isotropic etching process to form backside trench-shaped recesses. These recesses may then be filled with additional dielectric fill 1204. According to some embodiments, additional dielectric fill 1204 includes any suitable dielectric material, such as silicon dioxide. In some examples, additional dielectric fill 1204 includes the same dielectric material as dielectric walls 602.

FIGS. 13A and 13B are cross sectional views of the structure shown in FIGS. 12A and 12B following the formation of first backside conductive layer 1302 and second backside conductive layer 1304, according to some embodiments. Each of first backside conductive layer 1302 and second backside conductive layer 1304 may be part of a backside interconnect layer that may also include any number of other conductive lines extending through a backside dielectric layer. Backside contacts 1202 across FIG. 13A provide electrical connection between first backside conductive layer 1302 and a first subset of conductive fill 902 (e.g., first electrodes) and backside contacts 1202 across FIG. 13B provide electrical connection between second backside conductive layer 1304 and a second subset of conductive fill 902 (e.g., second electrodes). As noted above, first backside conductive layer 1302 or second backside conductive layer 1304 may be a power rail, ground rail, or signal line. Accordingly, the capacitor may include a first terminal made up of first electrodes coupled to first backside conductive layer 1302 as shown in FIG. 13A, and a second terminal made up of second electrodes coupled to second backside conductive layer 1304 as shown in FIG. 13B. The first electrodes alternate with the second electrodes along the third direction, according to some embodiments.

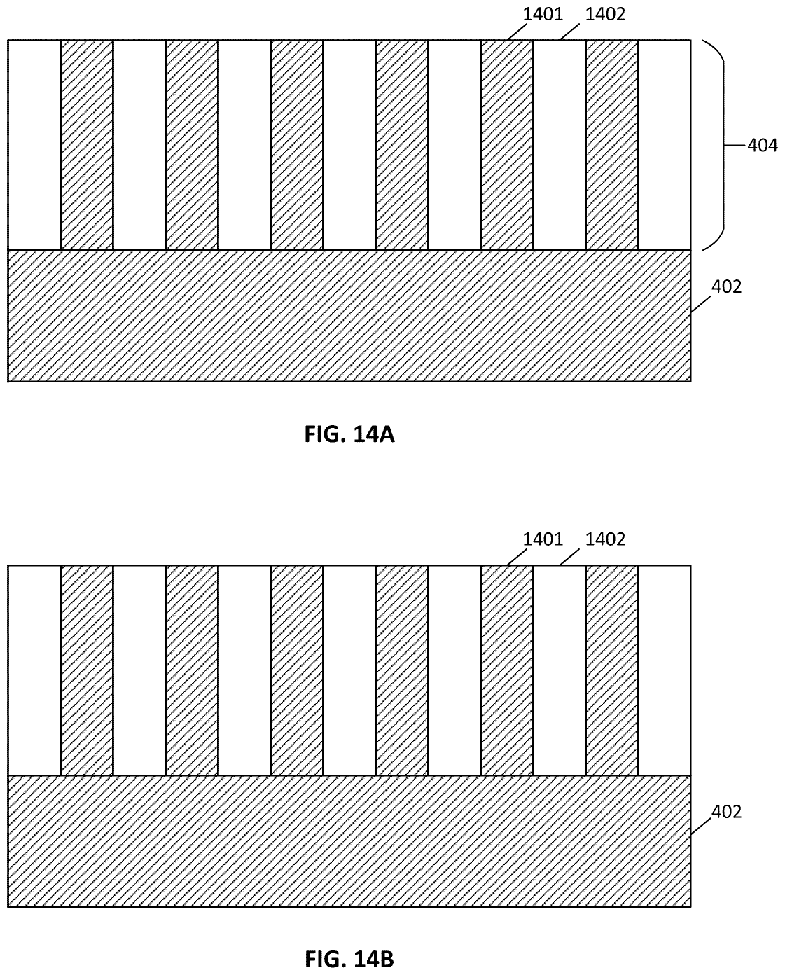

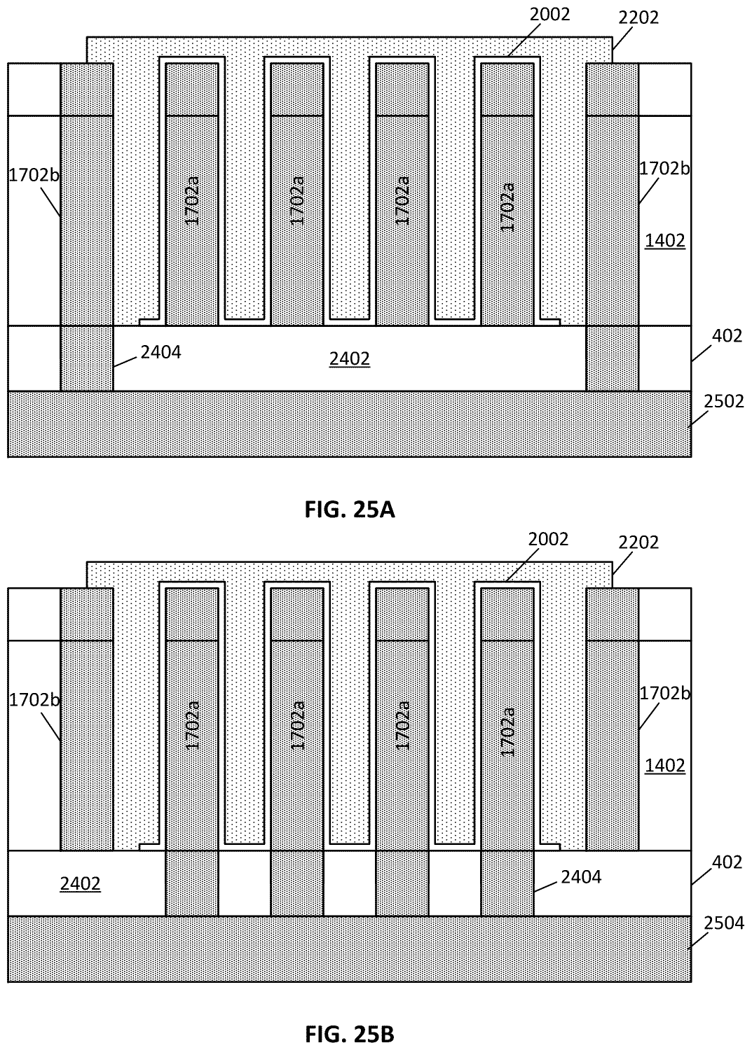

FIGS. 14A-25A and 14B-25B include cross-sectional views that collectively illustrate an example process for forming a portion of an integrated circuit having a second capacitor design using backside connections to backside conductive lines, in accordance with an embodiment of the present disclosure. FIGS. 14A-25A represent a similar cross-sectional view taken across plane B-B of FIG. 3A, while FIGS. 14B-25B represent a similar cross-sectional view taken across plane C-C of FIG. 3A. Each set of figures sharing the same letter shows an example structure that results from the process flow up to that point in time, so the depicted structure evolves as the process flow continues, culminating in the structures shown in FIGS. 25A and 25B, which is similar to the capacitor structure depicted in FIGS. 3A-3C. Such structures may be part of an overall integrated circuit (e.g., such as a processor or memory chip) that includes, for example, digital logic cells and/or memory cells and analog mixed signal circuitry. Thus, the illustrated portion of an integrated circuit structure may be part of a larger integrated circuit that includes other integrated circuitry not depicted. Example materials and process parameters are given, but the present disclosure is not intended to be limited to any specific such materials or parameters, as will be appreciated.

FIGS. 14A and 14B are cross sectional views of the structure shown in FIGS. 4A and 4B following the formation of dielectric walls 1402 alternating with semiconductor walls 1401 across device layer 404, according to some embodiments. Dielectric walls 1402 may be similar to dielectric walls 602 while semiconductor walls 1401 are similar to semiconductor walls 504 described above. In some embodiments, dielectric walls 1402 do not extend below a top surface of substrate 402.

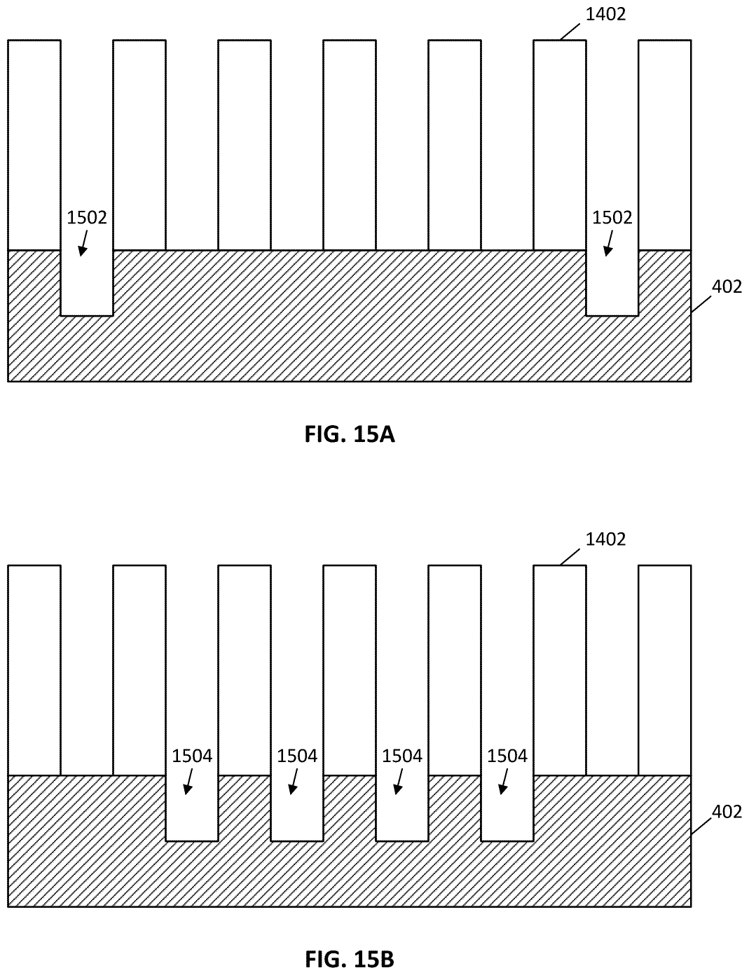

FIGS. 15A and 15B are cross sectional views of the structure shown in FIGS. 14A and 14B following the removal of semiconductor walls 1401 and selective removal of portions of substrate 402, according to some embodiments. Any number of RIE processes and lithography processes can be used to remove the semiconductor material of semiconductor walls 1401, and to selectively remove portions of substrate 402 at different ends of the trench-like recesses between dielectric walls 1402.

According to some embodiments, first cavities 1502 are formed by removing portions of substrate 402 adjacent to the outermost dielectric walls 1402 at one end of the trench-like recesses between dielectric walls 1402, and second cavities 1504 are formed by removing portions of substrate 402 between all other pairs of dielectric walls 1402 at the opposite end of the trench-like recesses (e.g., along the second direction into or out of the page). Each of first and second cavities 1502, 1504 may have substantially the same depth. In some examples, only one second cavity 1502 is formed while any number of adjacent second cavities 1504 are formed.

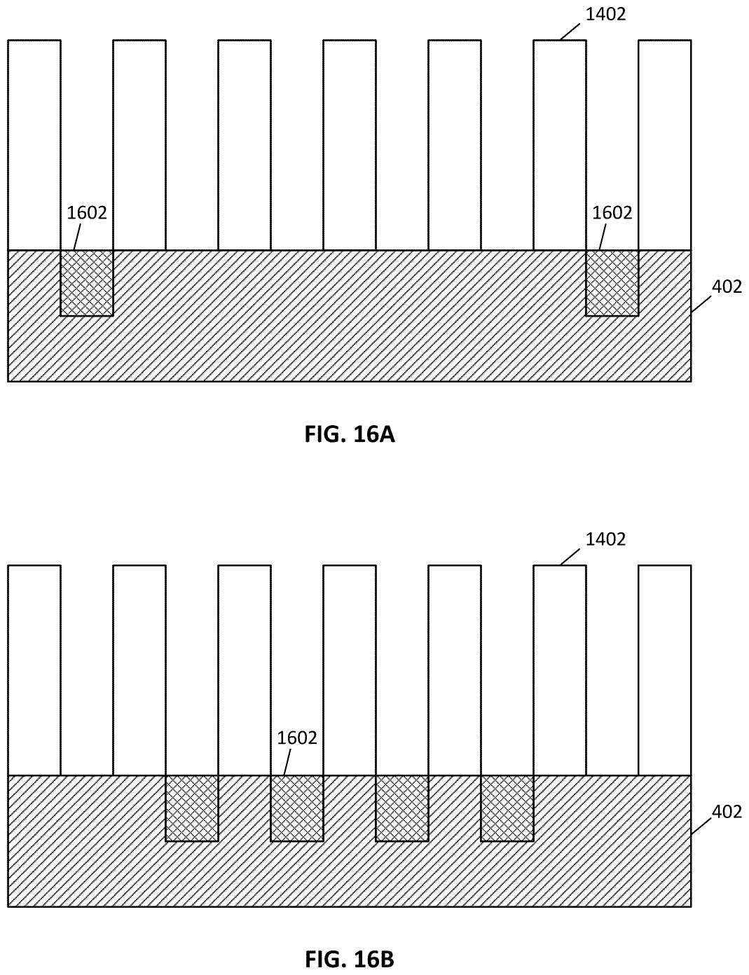

FIGS. 16A and 16B are cross sectional views of the structure shown in FIGS. 15A and 15B following the formation of sacrificial material 1602 within each of first cavities 1502 and second cavities 1504, according to some embodiments. Sacrificial material 1602 may be substantially similar to sacrificial material 802 described above. Sacrificial material 1602 may be recessed until a top surface of sacrificial material 1602 is near (e.g., within 10 nm) of a top surface of substrate 402.

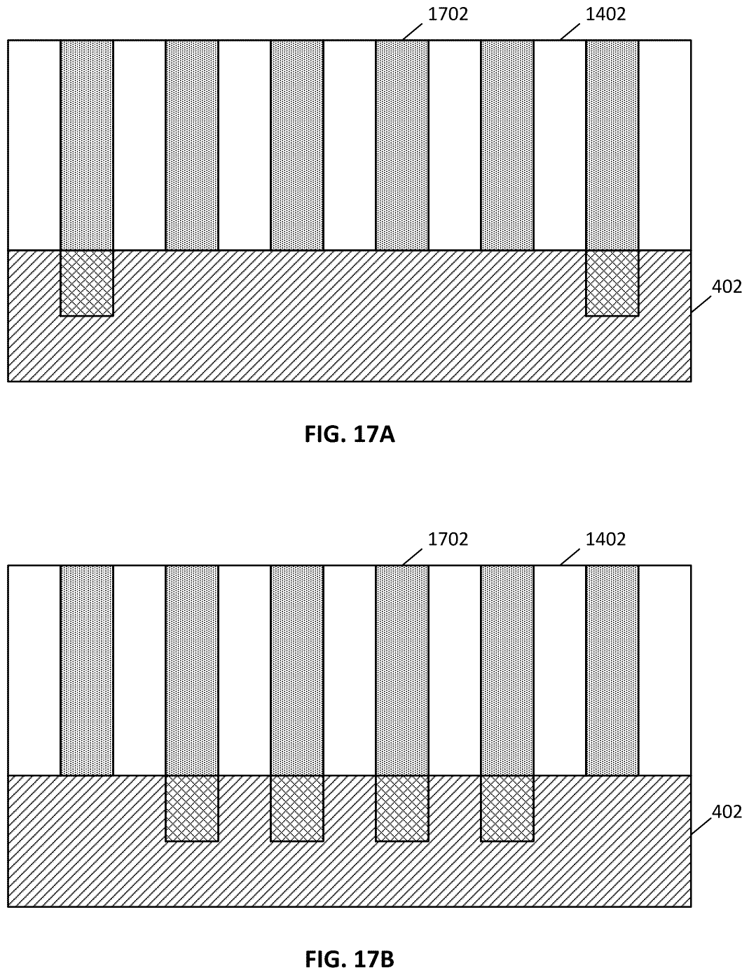

FIGS. 17A and 17B are cross sectional views of the structure shown in FIGS. 16A and 16B following the formation of conductive fill 1702 within the trench-like recesses between dielectric walls 1402, according to some embodiments. Conductive fill 1702 may be substantially similar to conductive fill 902 described above.

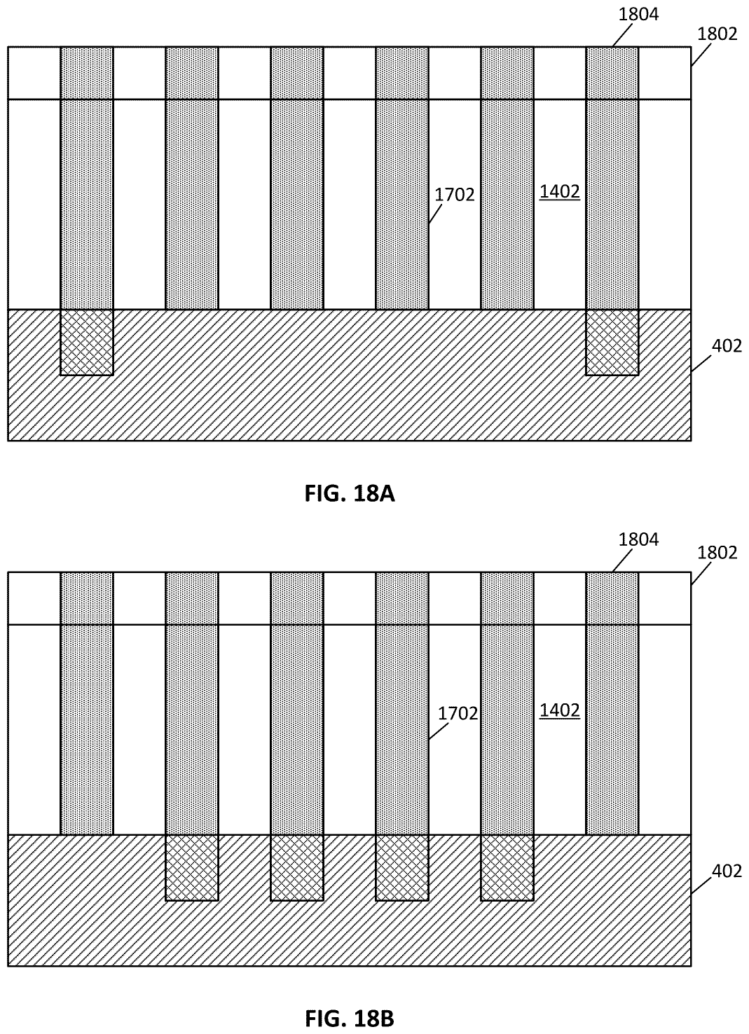

FIGS. 18A and 18B are cross sectional views of the structure shown in FIGS. 17A and 17B following the formation of a top dielectric layer 1802 and conductive caps 1804, according to some embodiments. Top dielectric layer 1802 may include any suitable dielectric material, such as silicon dioxide. In some examples, top dielectric layer 1802 includes the same dielectric material as dielectric walls 1402. Conductive caps 1804 may be provided through a thickness of top dielectric layer 1802 and contacting a top surface of conductive fill 1702. Due to possible alignment error, conductive caps 1804 may be slightly offset from conductive fill 1702. As noted above, conductive caps 1804 may include the same conductive material as conductive fill 1702. In some embodiments, conductive caps 1804 include any of tungsten, cobalt, ruthenium, or molybdenum.

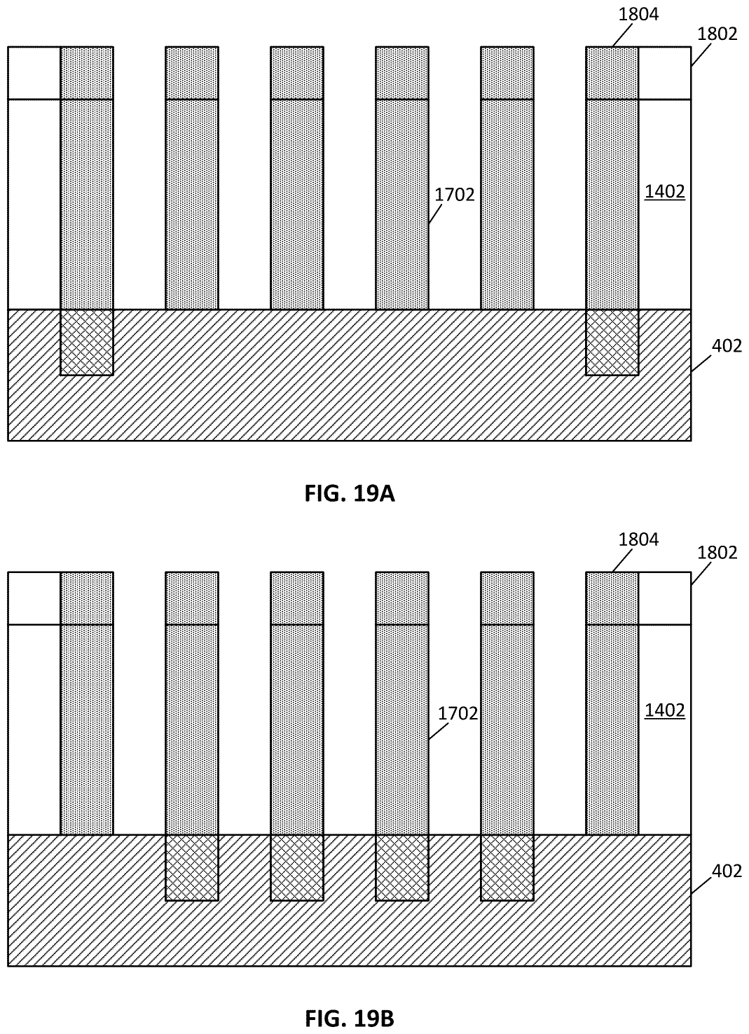

FIGS. 19A and 19B are cross sectional views of the structure shown in FIGS. 18A and 18B following the removal of dielectric walls 1402 from between inner adjacent pairs of conductive fill 1702. Any suitable isotropic etching process may be used to remove dielectric walls 1402, while masking outer dielectric walls 1402 or any other dielectric structures that should remain, according to some embodiments. According to some embodiments, exposed portions of top dielectric layer 1802 are also removed along with dielectric walls 1402.

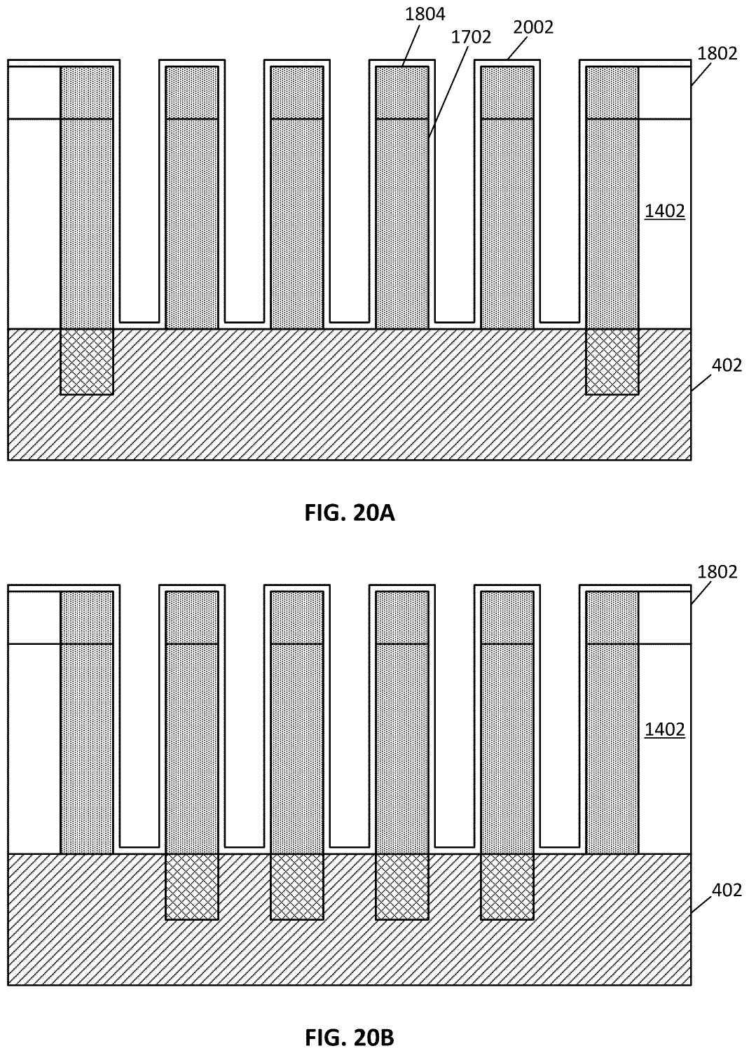

FIGS. 20A and 20B are cross sectional views of the structure shown in FIGS. 19A and 19B following the formation of a dielectric layer 2002, according to some embodiments. A conformal deposition technique, such as CVD or atomic layer deposition (ALD), may be used to form dielectric layer 2002 on all exposed surfaces. According to some embodiments, dielectric layer 2002 is formed over all exposed surfaces of conductive fill 1702 (and conductive caps 1804, if present). Dielectric layer 2002 may be any suitable dielectric material. In some embodiments, dielectric layer 2002 is high-k dielectric material, such as hafnium oxide or aluminum oxide. Dielectric layer 2002 may have a thickness between about 1 nm and about 5 nm.

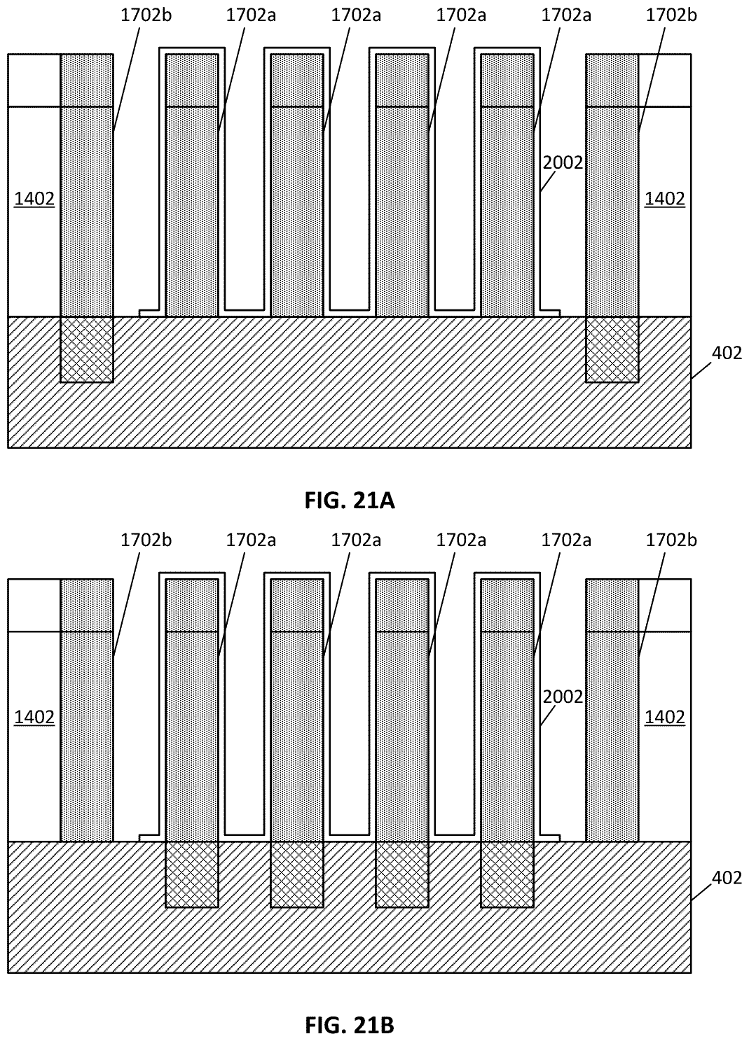

FIGS. 21A and 21B are cross sectional views of the structure shown in FIGS. 20A and 20B following a lithography process to remove portions of dielectric layer 2002, according to some embodiments. Any suitable lithography process may be used to mask a portion of dielectric layer 2002 on a subset of conductive fill 1702a while removing exposed portions of dielectric layer 2002 on any remaining conductive fill 1702b. According to some embodiments, subset of conductive fill 1702a are all laterally adjacent to one another and any remaining conductive fill 1702b are at either one end or both ends of subset of conductive fill 1702a. In the illustrated example, four laterally adjacent conductive fill 1702a are bookended on both sides by conductive fill 1702b, where dielectric layer 2002 remains on the four laterally adjacent conductive fill 1702a and has been removed from conductive fill 1702b.

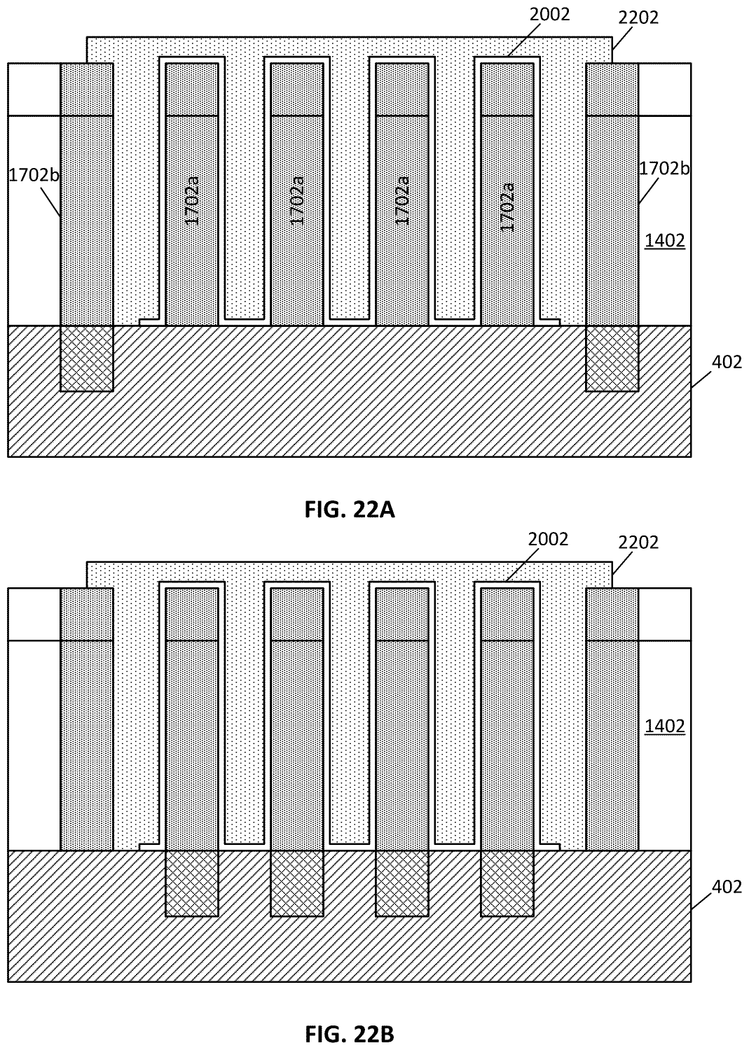

FIGS. 22A and 22B are cross sectional views of the structure shown in FIGS. 21A and 21B following the formation of a conductive layer 2202 over dielectric layer 2002, according to some embodiments. Conductive layer 2202 may be any suitable conductive material, such as tungsten, molybdenum, ruthenium, or cobalt. In some examples, conductive layer 2202 is the same conductive material as conductive fill 1702. According to some embodiments, conductive layer 2202 contacts at least one of conductive fill 1702b at either or both ends of the adjacent arrangement of conductive fill 1702a. Conductive layer 2202 is separated from conductive fill 1702a by dielectric layer 2002, according to some embodiments.

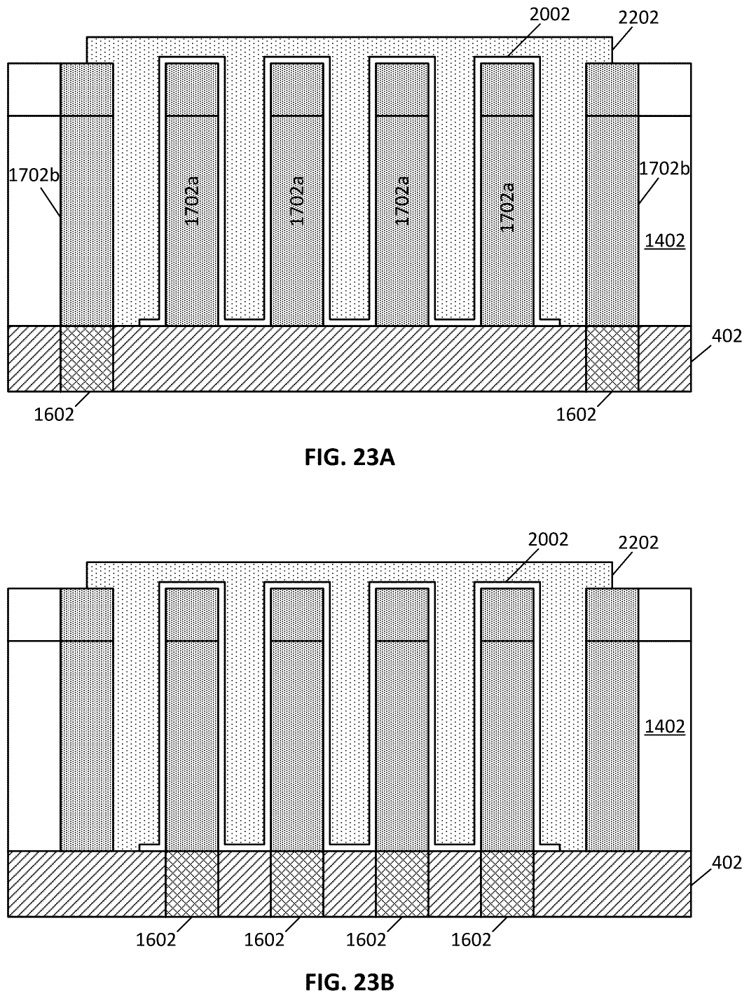

FIGS. 23A and 23B are cross sectional views of the structure shown in FIGS. 22A and 22B following the removal of at least a portion of substrate 402 from the backside, according to some embodiments. Substrate 402 may be removed using any number of grinding, polishing, or etching processes that remove semiconductor material. According to some embodiments, substrate 402 may be removed until a bottom surface of sacrificial material 1602 is exposed. In some embodiments, a portion of substrate 402 may remain laterally adjacent to sacrificial material 1602.

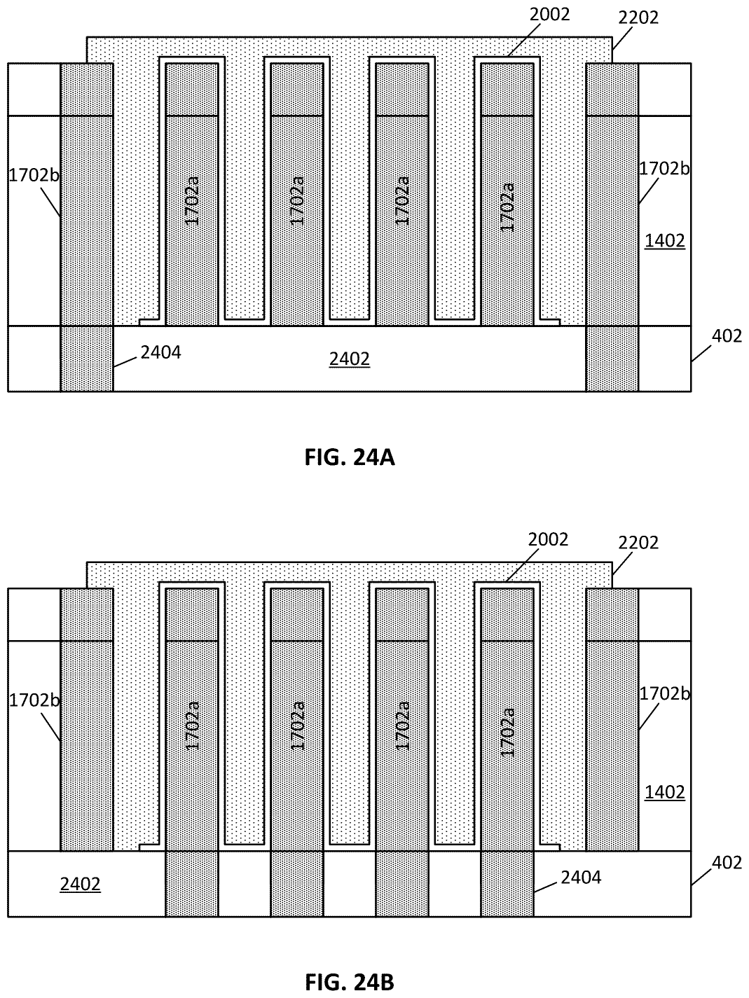

FIGS. 24A and 24B are cross sectional views of the structure shown in FIGS. 23A and 23B following the removal of any remaining portion of substrate 402 and subsequent formation of a dielectric fill 2402, and the replacement of sacrificial material 1602 with backside contacts 2404, according to some embodiments. The remaining semiconductor material of substrate 402 may be removed using an isotropic etching process from the backside to expose the bottom of the capacitor structure. The area between sacrificial material 1602 may then be filled with dielectric fill 2402. According to some embodiments, dielectric fill 2402 includes any suitable dielectric material, such as silicon dioxide. In some examples, dielectric fill 2402 includes the same dielectric material as dielectric walls 1402. A bottom surface of dielectric fill 2402 may be polished until a bottom surface of the sacrificial material 1602 is exposed.

An isotropic etching process may be used to remove sacrificial material 1602 from the backside to form backside cavities that expose portions of the bottom surfaces of conductive fill 1702. A conductive material may be formed within the backside cavities to form backside contacts 2404 on the bottom or backside surfaces of conductive fill 1702. Due to the arrangement of sacrificial material 1602, backside contacts 2404 follow the same arrangement on the bottom surfaces of conductive fill 1702. Thus, backside contacts 2404 are on the bottom surfaces of one end of conductive fill 1702b as seen in FIG. 24A and are on the bottom surfaces of the opposite end of conductive fill 1702a as seen in FIG. 24B.

FIGS. 25A and 25B are cross sectional views of the structure shown in FIGS. 24A and 24B following the formation of first backside conductive layer 2502 and second backside conductive layer 2504, according to some embodiments. Each of first backside conductive layer 2502 and second backside conductive layer 2504 may be part of a backside interconnect layer that may also include any number of other conductive lines extending through a backside dielectric layer. Backside contacts 2404 across FIG. 25A provide electrical connection between first backside conductive layer 2502 and one or more of conductive fill 1702b (e.g., one or more second electrodes) and backside contacts 2404 across FIG. 25B provide electrical connection between second backside conductive layer 2504 and a subset of conductive fill 1702a (e.g., first electrodes). As noted above, first backside conductive layer 2502 or second backside conductive layer 2504 may be a power rail, ground rail, or signal line. Accordingly, the capacitor may include a first terminal made up of first electrodes coupled to second backside conductive layer 2504 as shown in FIG. 25B, and a second terminal made up of conductive layer 2202 and one or more second electrodes coupled to first backside conductive layer 2502 as shown in FIG. 25A. According to some embodiments, the distance between the capacitor terminals is determined by the thickness of dielectric layer 2002.

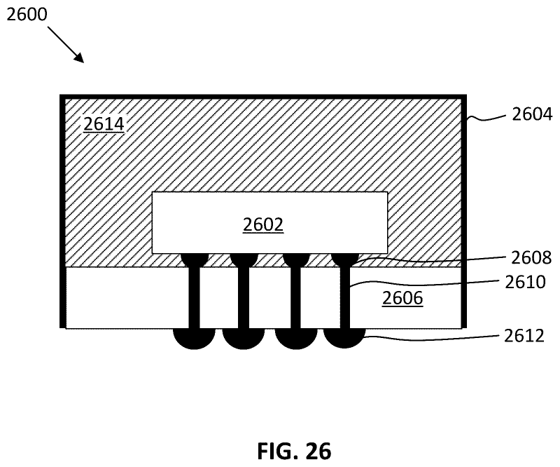

FIG. 26 illustrates an example embodiment of a chip package 2600, in accordance with an embodiment of the present disclosure. As can be seen, chip package 2600 includes one or more dies 2602. One or more dies 2602 may include at least one integrated circuit having a structure as described in any of the aforementioned embodiments. One or more dies 2602 may include any other circuitry used to interface with other devices formed on the dies, or other devices connected to chip package 2600, in some example configurations.

As can be further seen, chip package 2600 includes a housing 2604 that is bonded to a package substrate 2606. The housing 2604 may be any standard or proprietary housing, and may provide, for example, electromagnetic shielding and environmental protection for the components of chip package 2600. The one or more dies 2602 may be conductively coupled to a package substrate 2606 using connections 2608, which may be implemented with any number of standard or proprietary connection mechanisms, such as solder bumps, ball grid array (BGA), pins, or wire bonds, to name a few examples. Package substrate 2606 may be any standard or proprietary package substrate, but in some cases includes a dielectric material having conductive pathways (e.g., including conductive vias and lines) extending through the dielectric material between the faces of package substrate 2606, or between different locations on each face. In some embodiments, package substrate 2606 may have a thickness less than 1 millimeter (e.g., between 0.1 millimeters and 0.5 millimeters), although any number of package geometries can be used. Additional conductive contacts 2612 may be disposed at an opposite face of package substrate 2606 for conductively contacting, for instance, a printed circuit board (PCB). One or more vias 2610 extend through a thickness of package substrate 2606 to provide conductive pathways between one or more of connections 2608 to one or more of contacts 2612. Vias 2610 are illustrated as single straight columns through package substrate 2606 for case of illustration, although other configurations can be used (e.g., damascene, dual damascene, through-silicon via, or an interconnect structure that meanders through the thickness of substrate 2606 to contact one or more intermediate locations therein). In still other embodiments, vias 2610 are fabricated by multiple smaller stacked vias, or are staggered at different locations across package substrate 2606. In the illustrated embodiment, contacts 2612 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 2612, to inhibit shorting.

In some embodiments, a mold material 2614 may be disposed around the one or more dies 2602 included within housing 2604 (e.g., between dies 2602 and package substrate 2606 as an underfill material, as well as between dies 2602 and housing 2604 as an overfill material). Although the dimensions and qualities of the mold material 2614 can vary from one embodiment to the next, in some embodiments, a thickness of mold material 2614 is less than 1 millimeter. Example materials that may be used for mold material 2614 include epoxy mold materials, as suitable. In some cases, the mold material 2614 is thermally conductive, in addition to being electrically insulating.

### Example System

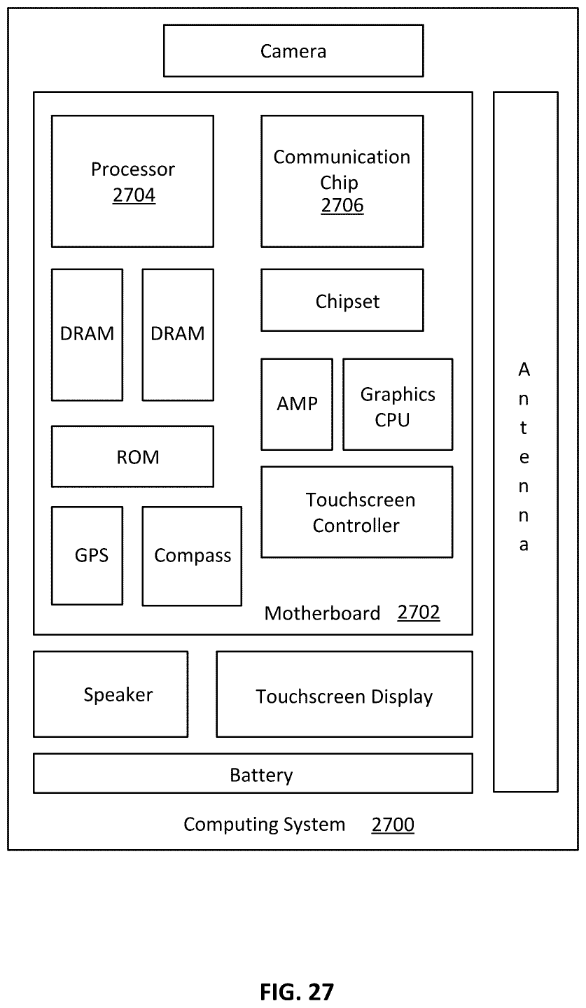

FIG. 27 is an example computing system implemented with one or more of the integrated circuit structures as disclosed herein, in accordance with some embodiments of the present disclosure. As can be seen, the computing system 2700 houses a motherboard 2702. The motherboard 2702 may include a number of components, including, but not limited to, a processor 2704 and at least one communication chip 2706, each of which can be physically and electrically coupled to the motherboard 2702, or otherwise integrated therein. As will be appreciated, the motherboard 2702 may be, for example, any printed circuit board (PCB), whether a main board, a daughterboard mounted on a main board, or the only board of system 2700, etc.

Depending on its applications, computing system 2700 may include one or more other components that may or may not be physically and electrically coupled to the motherboard 2702. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 2700 may include one or more integrated circuit structures or devices configured in accordance with any of the embodiments disclosed herein (e.g., a module including an integrated circuit having one or more capacitors coupled to backside power rails or signal lines). In some embodiments, multiple functions can be integrated into one or more chips (e.g., for instance, note that the communication chip 2706 can be part of or otherwise integrated into the processor 2704).

The communication chip 2706 enables wireless communications for the transfer of data to and from the computing system 2700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 2706 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 2700 may include a plurality of communication chips 2706. For instance, a first communication chip 2706 may be dedicated to shorter range wireless communications such as Wi-Fi and Bluetooth and a second communication chip 2706 may be dedicated to longer range wireless communications such as GPS, EDGE, GPRS, CDMA, WiMAX, LTE, Ev-DO, and others.

The processor 2704 of the computing system 2700 includes an integrated circuit die packaged within the processor 2704. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 2706 also may include an integrated circuit die packaged within the communication chip 2706. In accordance with some such example embodiments, the integrated circuit die of the communication chip includes one or more semiconductor devices as variously described herein. As will be appreciated in light of this disclosure, note that multi-standard wireless capability may be integrated directly into the processor 2704 (e.g., where functionality of any chips 2706 is integrated into processor 2704, rather than having separate communication chips). Further note that processor 2704 may be a chip set having such wireless capability. In short, any number of processor 2704 and/or communication chips 2706 can be used. Likewise, any one chip or chip set can have multiple functions integrated therein.

In various implementations, the computing system 2700 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 2700 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a plurality of semiconductor devices in a device layer and a capacitor within a dielectric region that is laterally adjacent to the device layer. The capacitor includes a plurality of first electrodes, each having a height in a first direction through an entire thickness of the dielectric region and having a length along a second direction, a plurality of second electrodes, each having a height in the first direction through the entire thickness of the dielectric region and having a length along the second direction, a first plurality of contacts on a backside of the plurality of first electrodes, and a second plurality of contacts on a backside of the plurality of second electrodes. The first plurality of contacts are beneath a bottom surface of the plurality of first electrodes and the second plurality of contacts are beneath a bottom surface of the plurality of second electrodes. The plurality of first electrodes alternates with the plurality of second electrodes along a third direction substantially orthogonal to the second direction.

Example 2 includes the integrated circuit of Example 1, further comprising a metal cap on top surfaces of each of the plurality of first electrodes and each of the plurality of second electrodes.

Example 3 includes the integrated circuit of Example 1 or 2, further comprising a first metal layer beneath the first plurality of contacts and contacting each of the first plurality of contacts, and a second metal layer beneath the second plurality of contacts and contacting each of the second plurality of contacts.

Example 4 includes the integrated circuit of Example 3, wherein the first metal layer and the second metal layer are power and ground rails, respectively.

Example 5 includes the integrated circuit of Example 3, wherein one or both of the first metal layer and the second metal layer is a signal line.

Example 6 includes the integrated circuit of any one of Examples 1-5, wherein the plurality of first electrodes and the plurality of second electrodes comprises tungsten.

Example 7 includes the integrated circuit of any one of Examples 1-6, wherein the height of each of the first and second electrodes is between about 50 nm and about 150 nm.

Example 8 includes the integrated circuit of any one of Examples 1-7, wherein the first direction is substantially orthogonal to both the second and third directions.

Example 9 includes the integrated circuit of any one of Examples 1-8, wherein the plurality of first electrodes comprise a first plurality of conductive plates, and the plurality of second electrodes comprise a second plurality of conductive plates.

Example 10 includes the integrated circuit of any one of Examples 1-9, wherein the dielectric region has a top surface that is substantially coplanar with a top surface of the device layer.

Example 11 includes the integrated circuit of any one of Examples 1-10, further comprising dielectric material between each of a plurality of electrode pairs, each electrode pair including one of the first electrodes and one of the second electrodes.

Example 12 includes the integrated circuit of Example 11, wherein the dielectric material comprises high-k dielectric material.

Example 13 includes the integrated circuit of Example 12, wherein the high-k dielectric material comprises hafnium oxide or aluminum oxide.

Example 14 includes the integrated circuit of any one of Examples 1-13, wherein there are four or more of the first electrodes, and four or more of the second electrodes.

Example 15 is a printed circuit board comprising the integrated circuit of any one of Examples 1-14.

Example 16 is an integrated circuit that includes a plurality of semiconductor devices in a device layer, and a capacitor within a dielectric region that is laterally adjacent to the device layer. The capacitor includes a plurality of first electrodes, each having a height in a first direction, a length along a second direction, and arranged parallel to one another along a third direction, one or more second electrodes, each having a height in the first direction, a length along the second direction, and arranged parallel to the plurality of first electrodes along the third direction, a dielectric layer on the plurality of first electrodes, a conductive layer on the dielectric layer and between two or more of the plurality of first electrodes, a first plurality of contacts on a backside of the plurality of first electrodes, and one or more second contacts on a backside of the one or more second electrodes. The conductive layer contacts at least one of the one or more second electrodes. The first plurality of contacts are beneath a bottom surface of the plurality of first electrodes and the one or more second contacts are beneath a bottom surface of the one or more second electrodes.

Example 17 includes the integrated circuit of Example 16, further comprising a metal cap on top surfaces of each of the plurality of first electrodes and each of the one or more second electrodes.

Example 18 includes the integrated circuit of Example 16 or 17, further comprising a first metal layer beneath the first plurality of contacts and contacting each of the first plurality of contacts, and a second metal layer beneath the one or more second contacts and contacting each of the one or more second contacts.

Example 19 includes the integrated circuit of Example 18, wherein the first metal layer and the second metal layer are power and ground rails, respectively.

Example 20 includes the integrated circuit of Example 18, wherein one or both of the first metal layer and the second metal layer is a signal line.

Example 21 includes the integrated circuit of any one of Examples 16-20, wherein the plurality of first electrodes and the one or more second electrodes comprises tungsten.

Example 22 includes the integrated circuit of any one of Examples 16-21, wherein the height of each of first and second electrodes is between about 50 nm and about 150 nm.

Example 23 includes the integrated circuit of any one of Examples 16-22, wherein the first direction is substantially orthogonal to both the second and third directions.

Example 24 includes the integrated circuit of any one of Examples 16-23, wherein the plurality of first electrodes comprise a plurality of first conductive plates, and the one or more second electrodes comprise one or more second conductive plates.

Example 25 includes the integrated circuit of any one of Examples 16-24, wherein the dielectric region has a top surface that is substantially coplanar with a top surface of the device layer.

Example 26 includes the integrated circuit of any one of Examples 16-25, wherein the dielectric layer comprises a high-k dielectric material.

Example 27 includes the integrated circuit of Example 26, wherein the high-k dielectric material comprises hafnium oxide or aluminum oxide.

Example 28 includes the integrated circuit of any one of Examples 16-27, wherein the conductive layer comprises tungsten.

Example 29 includes the integrated circuit of any one of Examples 16-28, wherein the plurality of first electrodes are arranged adjacent to one another in a line along the third direction, and the one or more second electrodes comprise one second electrode at one end of the line of first electrodes and another second electrode at an opposite end of the line of first electrodes.

Example 30 is a printed circuit board comprising the integrated circuit of any one of Examples 16-29.

Example 31 is an electronic device that includes a chip package having one or more dies. At least one of the one or more dies includes a plurality of first electrodes of a capacitor, each having a height in a first direction through an entire thickness of a dielectric region and each having a length along a second direction, a plurality of second electrodes of the capacitor, each having a height in the first direction through the entire thickness of the dielectric region and each having a length along the second direction, a first plurality of contacts on a backside of the plurality of first electrodes, and a second plurality of contacts on a backside of the plurality of second electrodes. The first plurality of contacts are beneath a bottom surface of the plurality of first electrodes and the second plurality of contacts are beneath a bottom surface of the plurality of second electrodes. The plurality of first electrodes alternates with the plurality of second electrodes along a third direction substantially orthogonal to the second direction.

Example 32 includes the electronic device of Example 31, wherein the at least one of the one or more dies further comprises a metal cap on top surfaces of each of the plurality of first electrodes and each of the plurality of second electrodes.

Example 33 includes the electronic device of Example 31 or 32, wherein the at least one of the one or more dies further comprises a first metal layer beneath the first plurality of contacts and contacting each of the first plurality of contacts, and a second metal layer beneath the second plurality of contacts and contacting each of the second plurality of contacts.

Example 34 includes the electronic device of Example 33, wherein the first metal layer and the second metal layer are power and ground rails, respectively.

Example 35 includes the electronic device of any one of Examples 31-34, wherein the plurality of first electrodes and the plurality of second electrodes comprises tungsten.

Example 36 includes the electronic device of any one of Examples 31-35, wherein the height of each of the first and second electrodes is between about 50 nm and about 150 nm.

Example 37 includes the electronic device of any one of Examples 31-36, wherein the first direction is substantially orthogonal to both the second and third directions.

Example 38 includes the electronic device of any one of Examples 31-37, wherein the plurality of first electrodes comprise a first plurality of conductive plates, and the plurality of second electrodes comprise a second plurality of conductive plates.

Example 39 includes the electronic device of any one of Examples 31-38, further comprising dielectric material between each of a plurality of electrode pairs, each electrode pair including one of the first electrodes and one of the second electrodes.

Example 40 includes the electronic device of any one of Examples 31-39, further comprising a printed circuit board, wherein the chip package is attached to the printed circuit board.

Example 41 is an electronic device that includes a chip package having one or more dies. At least one of the one or more dies includes a plurality of first electrodes of a capacitor and arranged parallel to one another along a third direction, each first electrode having a height in a first direction and a length along a second direction, one or more second electrodes of the capacitor and arranged parallel to the plurality of first electrodes along the third direction, each second electrode having a height in the first direction and a length along the second direction, a dielectric layer on the plurality of first electrodes, a conductive layer on the dielectric layer and between two or more of the plurality of first electrodes, a first plurality of contacts on a backside of the plurality of first electrodes, and one or more second contacts on a backside of the one or more second electrodes. The conductive layer contacts at least one of the one or more second electrodes. The first plurality of contacts are beneath a bottom surface of the plurality of first electrodes and the one or more second contacts are beneath a bottom surface of the one or more second electrodes.

Example 42 includes the electronic device of Example 41, wherein the at least one of the one or more dies further comprises a metal cap on top surfaces of each of the plurality of first electrodes and each of the one or more second electrodes.

Example 43 includes the electronic device of Example 41 or 42, wherein the at least one of the one or more dies further comprises a first metal layer beneath the first plurality of contacts and contacting each of the first plurality of contacts, and a second metal layer beneath the one or more second contacts and contacting each of the one or more second contacts.

Example 44 includes the electronic device of Example 43, wherein the first metal layer and the second metal layer are power and ground rails, respectively.

Example 45 includes the electronic device of any one of Examples 41-44, wherein the plurality of first electrodes and the one or more second electrodes comprises tungsten.

Example 46 includes the electronic device of any one of Examples 41-45, wherein the height of each of first and second electrodes is between about 50 nm and about 150 nm.

Example 47 includes the electronic device of any one of Examples 41-46, wherein the first direction is substantially orthogonal to both the second and third directions.

Example 48 includes the electronic device of any one of Examples 41-47, wherein the plurality of first electrodes comprise a plurality of first conductive plates, and the one or more second electrodes comprise one or more second conductive plates.

Example 49 includes the electronic device of any one of Examples 41-48, wherein the dielectric layer comprises a high-k dielectric material.

Example 50 includes the electronic device of any one of Examples 41-49, wherein the conductive layer comprises tungsten.

Example 51 includes the electronic device of any one of Examples 41-50, wherein the plurality of first electrodes are arranged adjacent to one another in a line along the third direction, and the one or more second electrodes comprise one second electrode at one end of the line of first electrodes and another second electrode at an opposite end of the line of first electrodes.

Example 52 includes the electronic device of any one of Examples 41-51, further comprising a printed circuit board, wherein the chip package is attached to the printed circuit board.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit, comprising:
a plurality of semiconductor devices in a device layer; and
a capacitor within a dielectric region laterally adjacent to the device layer, the capacitor comprising
a plurality of first electrodes, each having a height in a first direction through an entire thickness of the dielectric region, and each having a length along a second direction,
a plurality of second electrodes, each having a height in the first direction through the entire thickness of the dielectric region, and each having a length along the second direction,
a first plurality of contacts on a backside of the plurality of first electrodes, such that the first plurality of contacts are beneath a bottom surface of the plurality of first electrodes, and
a second plurality of contacts on a backside of the plurality of second electrodes, such that the second plurality of contacts are beneath a bottom surface of the plurality of second electrodes,
wherein the plurality of first electrodes alternates with the plurality of second electrodes along a third direction substantially orthogonal to the second direction.

2. The integrated circuit of claim 1, further comprising:
a first metal layer beneath the first plurality of contacts and contacting each of the first plurality of contacts; and
a second metal layer beneath the second plurality of contacts and contacting each of the second plurality of contacts.

3. The integrated circuit of claim 2, wherein the first metal layer and the second metal layer are power and ground rails, respectively.

4. The integrated circuit of claim 1, wherein the height of each of the first and second electrodes is between about 50 nm and about 150 nm.

5. The integrated circuit of claim 1, wherein the first direction is substantially orthogonal to both the second and third directions.

6. The integrated circuit of claim 1, wherein the plurality of first electrodes comprise a first plurality of conductive plates, and the plurality of second electrodes comprise a second plurality of conductive plates.

7. The integrated circuit of claim 1, further comprising dielectric material between each of a plurality of electrode pairs, each electrode pair including one of the first electrodes and one of the second electrodes.

8. The integrated circuit of claim 1, wherein there are four or more of the first electrodes, and four or more of the second electrodes.

9. A printed circuit board comprising the integrated circuit of claim 1.

10. An integrated circuit, comprising:
a plurality of semiconductor devices in a device layer; and
a capacitor within a dielectric region adjacent to the device layer, the capacitor comprising
a plurality of first electrodes arranged parallel to one another along a third direction, each first electrode having a height in a first direction, a length along a second direction,
one or more second electrodes arranged parallel to the plurality of first electrodes along the third direction, each having a height in the first direction, a length along the second direction,
a dielectric layer on the plurality of first electrodes,
a conductive layer on the dielectric layer and between two or more of the plurality of first electrodes, wherein the conductive layer contacts at least one of the one or more second electrodes,
a first plurality of contacts on a backside of the plurality of first electrodes, such that the first plurality of contacts are beneath a bottom surface of the plurality of first electrodes, and
one or more second contacts on a backside of the one or more second electrodes, such that the one or more second contacts are beneath the bottom surface of the one or more second electrodes.

11. The integrated circuit of claim 10, further comprising:
a first metal layer beneath the first plurality of contacts and contacting each of the first plurality of contacts; and
a second metal layer beneath the one or more second contacts and contacting each of the one or more second contacts.

12. The integrated circuit of claim 11, wherein the first metal layer and the second metal layer are power and ground rails, respectively.

13. The integrated circuit of claim 10, wherein the first direction is substantially orthogonal to both the second and third directions.

14. The integrated circuit of claim 10, wherein the plurality of first electrodes comprise a plurality of first conductive plates, and the one or more second electrodes comprise one or more second conductive plates.

15. The integrated circuit of claim 10, wherein the dielectric layer comprises a high-k dielectric material.

16. The integrated circuit of claim 15, wherein the high-k dielectric material comprises hafnium oxide or aluminum oxide.

17. The integrated circuit of claim 10, wherein the conductive layer comprises tungsten.

18. The integrated circuit of claim 10, wherein the plurality of first electrodes are arranged adjacent to one another in a line along the third direction, and the one or more second electrodes comprise one second electrode at one end of the line of first electrodes and another second electrode at an opposite end of the line of first electrodes.

19. A printed circuit board comprising the integrated circuit of claim 10.

20. An electronic device, comprising:
a chip package comprising one or more dies, at least one of the one or more dies comprising
a plurality of first electrodes of a capacitor, each having a height in a first direction through an entire thickness of a dielectric region, and each having a length along a second direction,
a plurality of second electrodes of the capacitor, each having a height in the first direction through the entire thickness of the dielectric region, and each having a length along the second direction,
a first plurality of contacts on a backside of the plurality of first electrodes, such that the first plurality of contacts are beneath a bottom surface of the plurality of first electrodes, and
a second plurality of contacts on a backside of the plurality of second electrodes, such that the second plurality of contacts are beneath a bottom surface of the plurality of second electrodes,
wherein the plurality of first electrodes alternates with the plurality of second electrodes along a third direction substantially orthogonal to the second direction.
